(19) United States
(12) Patent Application Publication
(10) Pub. No.: US 2022/0122878 A1
(43) Pub. Date: Apr. 21, 2022

(54) AUTOMATED PROCESS MODULE RING POSITIONING AND REPLACEMENT

(71) Applicant: Lam Research Corporation, Fremont, CA (US)

(72) Inventors: Joanna Wu, Redwood City, CA (US); Hui Ling Han, Alameda, CA (US); Christopher Kimball, Fremont, CA (US); Jim Tappan, Fremont, CA (US); Griff O'Neill, Fremont, CA (US); John Drewery, Fremont, CA (US)

(21) Appl. No.: 17/605,545

(22) PCT Filed: Apr. 22, 2020
(86) PCT No.: PCT/US20/29408

§ 371 Date: Oct. 21, 2021

Related U.S. Application Data
(60) Provisional application No. 62/846,579, filed on May 10, 2019.

(51) Int. Cl. H01L 21/687; H01J 37/20; H01J 37/32

(52) U.S. Cl. CPC H01L 21/68742; H01J 37/32715; H01J 37/20

(57) ABSTRACT

A lift pin mechanism employed within a process module includes a plurality of lift pins distributed uniformly along a circumference of a lower electrode defined in the process module. Each lift pin includes a top member that is separated from a bottom member by a collar defined by a chamfer. A sleeve is defined in a housing within a body of the lower electrode on which a substrate is received for processing. The housing is disposed below a mid ring that is defined in the lower electrode. The collar of the lift pin is used to engage with a bottom side of the sleeve, and a top side of the sleeve is configured to engage with the mid ring, when the lift pins are activated. An actuator coupled to each of the plurality of lift pins and an actuator drive connected to the actuators is used to drive the plurality of lift pins. A controller is coupled to the actuator drive to control movement of the plurality of lift pins.

### FIELD OF THE INVENTION

The present embodiments relate to a substrate processing system used in manufacturing semiconductor substrate, and more particularly, to a lift pin mechanism that is used for replacing a top ring and a mid ring used in a process module of the substrate processing system.

### BACKGROUND

### Description of the Related Art

A typical substrate processing system used in processing a semiconductor substrate includes a substrate storage box (otherwise referred to as “substrate storage station” or a front opening unified pod (FOUP)), that is used to deliver and store substrates, an equipment front end module (EFEM) that interfaces between the FOUP and a first side of one or more loadlock chambers (otherwise referred to as “airlocks”), a vacuum transfer module coupled to a second side of the one or more airlocks and one or more process modules that are coupled to the vacuum transfer module. Each process module is used to perform a specific manufacturing operation, such as a cleaning operation, a deposition, an etching operation, a rinsing operation, a drying operation, etc. The chemistries and/or processing conditions used to perform these operations cause damage to some of the hardware components of the process module that are constantly exposed to the harsh conditions within the process module. These damaged or worn out hardware components need to be replaced periodically and promptly to ensure that these damaged components do not expose other underlying hardware components in the process module to the harsh conditions during semiconductor substrate processing. The hardware component maybe, for example, a top ring, such as an edge ring, that is disposed immediately adjacent to a semiconductor substrate within a process module. During an etching operation, the top ring, based on its location, may get damaged due to its continuous exposure to ion bombardment from plasma generated within the process module that is used in the etching operation. The damaged top ring needs to be replaced promptly to ensure that the damaged top ring does not expose other underlying hardware components, such as the remaining components of an electrostatic chuck or a pedestal, to the harsh process conditions. The hardware components that can be replaced are referred to herein as consumable parts.

The current process of replacing the damaged consumable part requires the consumable part, such as the top ring, to be accurately positioned along a horizontal coordinate plane (e.g., ring transfer plane) for hand-off to the lift pins within a process module. Due to very limited space within the process module, precise handing of the consumable part is especially important to ensure the hand-off occurs reliably.

It is in this context that embodiments of the invention arise.

### SUMMARY

Embodiments of the invention define a lift pin mechanism employed within a process module of a substrate processing system that is designed to remove and replace damaged hardware components, such as a top ring (e.g., edge ring) and a mid ring, of a process module disposed within the substrate processing system, without a need to break vacuum (i.e., expose the substrate processing system to Atmospheric condition). A damaged hardware component that can be replaced is also referred to herein as a consumable part. The substrate processing system includes one or more process modules, with each process module configured to perform a semiconductor substrate processing operation. As the consumable part in a process module gets exposed to the harsh chemicals and process conditions within, the consumable part gets damaged and needs to be replaced in a timely manner The damaged consumable part has to be replaced promptly so as to prevent compromising underlying hardware components of the process module.

The damaged consumable part (e.g., top/edge ring or mid ring) may be replaced without opening the substrate processing system by mounting a detachable ring storage station to the substrate processing system. The ring storage station is similar to a substrate storage station that provides the substrate for processing. The ring storage station includes a plurality of compartments stacked horizontally for receiving and storing the consumable parts (i.e., both new and used consumable parts). The ring storage station and the process module(s) are coupled to a controller to enable the controller to coordinate access to the ring storage station and the various process modules while the process modules are maintained in a vacuum state, so as to allow replacement of the consumable part in the respective process modules.

To provide easy access to the damaged consumable part, a process module of the substrate processing system is designed to include a lift pin mechanism. When engaged, the lift pin mechanism is configured to allow the consumable part to be moved from an installed position to a replacement position so that an end-effector of a robot available within the substrate processing system may be used to access and retrieve the raised consumable part from the process module. A replacement consumable part (i.e., new consumable part) is retrieved from the ring storage station and delivered to the process module and the lift pin mechanism is used to receive the new consumable part and lower it into position in the process module.

The design of the ring storage station and the substrate processing system is such that a need to open the substrate processing system to Atmospheric conditions in order to access the damaged consumable part, is eliminated. For example, the substrate processing system may include an equipment front end module (EFEM) maintained at Atmospheric condition. A first side of the EFEM may be coupled to one or more substrate storage stations (e.g., FOUPs) for transferring substrates into and out of the substrate processing system. In addition to substrate storage stations, the first side or a different side of the EFEM may be coupled to one or more ring storage stations. A second side of the EFEM may interface with a vacuum transfer module through one or more loadlock chambers, such as airlocks. One or more process modules may be coupled to the vacuum transfer module.

A robot of the EFEM may be used to transport the consumable part between the ring storage station and the airlock. In such implementations, the airlock acts as an interface by allowing the consumable part to be received from the EFEM while the airlock is maintained at Atmospheric condition. After receiving the consumable part, the airlock is pumped to vacuum, and a robot of the vacuum transfer module is used to move the consumable part to the process module. A robot of the vacuum transfer module is used to move the consumable part into the process module. A lift pin mechanism within the process module provides access to the consumable part by raising and lowering the consumable part, so that the replacement of the consumable part can be carried out by the robot of the vacuum transfer module in vacuum conditions.

The robot of the vacuum transfer module and the lift pin mechanism of the process module together allow precision delivery and retrieval of the consumable part thereby eliminating the risk of damage to any hardware components of the process modules during replacement of the consumable part. As the consumable part is being moved into the process module in a controlled manner, the time required to recondition the process module to bring it to an active operation state after replacement of the damaged consumable part, is substantially reduced.

In alternate implementations, the ring storage station may be maintained at vacuum and coupled to the process module directly or through the vacuum transfer module of the substrate processing system. The robot of the vacuum transfer module may be used to move the consumable part between the ring storage station and the process module without breaking vacuum, so that the consumable part may be replaced without risk of contamination. Consequently, the time required to recondition the process module to bring to an active operation state after replacement of the damaged consumable part, is substantially reduced.

In one embodiment, a lift pin mechanism is disclosed. The lift pin mechanism is employed within a process module of a substrate processing system and is used for exchanging consumable parts (e.g., top ring or mid ring) of the process module. The lift pin mechanism includes a plurality of lift pins that are distributed uniformly along a circumference of a lower electrode (e.g., a pedestal or an electrostatic chuck) defined in the process module. Each lift pin includes a top member and a bottom member. The top member is separated from the bottom member by a collar defined by a chamfer The top member is configured to extend through a sleeve defined in a housing within a body of a lower electrode disposed in the process module and engage with an underside surface of a top ring used in the process module. The collar of the lift pin is configured to engage with a bottom surface of the sleeve. A top surface of the sleeve is configured to engage with a bottom side of the mid ring, when the plurality of lift pins is activated. An actuator is coupled to each of the plurality of lift pins. The actuators are connected to an actuator drive that provides power to drive the actuators. A controller is coupled to the actuator drive and is configured to provide control signals to control movement of the plurality of lift pins.

In another embodiment, a process module used within a substrate processing system, is disclosed. The process module includes a top electrode with a plurality of outlets distributed uniformly along a horizontal plane. The plurality of outlets is connected to a process chemistry source and is configured to provide process chemistry to the process module for generating plasma. The top electrode is electrically grounded. A lower electrode is disposed opposite to the top electrode and is configured to support the substrate received for processing. The lower electrode is connected to a power source to provide power to generate the plasma. The lower electrode includes a bottom ring disposed within a body proximal to an outer edge. A housing extends from a top surface of the bottom ring downward into a body of the bottom ring. The housing is configured to house a sleeve. A mid ring is disposed immediately above the bottom ring and is aligned with the bottom ring. The mid ring includes a channel that extends vertically from a top surface to a bottom surface of the mid ring. A top ring is disposed immediately above the mid ring and aligned with the mid ring such that a top surface of the top ring is co-planar with a top surface of the substrate, when the substrate is received on the lower electrode. A lift pin mechanism is defined in the body of the lower electrode. The lift pin mechanism includes a plurality of lift pins. Each lift pin includes a top member and a bottom member. The top member is separated from the bottom member by a collar defined by a chamfer. The plurality of lift pins are distributed uniformly along a circumference of the lower electrode so as to align with the bottom ring, the mid ring and the top ring. An actuator is coupled to each of the lift pins. The actuators of the plurality of lift pins are connected to an actuator drive that provides power to drive the actuators.

Other aspects of the invention will become apparent from the following detailed description, taken in conjunction with the accompanying drawings, illustrating by way of example the principles of the invention.

### BRIEF DESCRIPTION OF THE DRAWINGS

The invention may best be understood by reference to the following description taken in conjunction with the accompanying drawings.

FIG. 1 illustrates a simplified block diagram of a substrate processing system that includes a process module with a lift pin mechanism for providing access to a consumable part, in one implementation.

FIG. 2 illustrates a simplified block diagram of a process module included in a substrate processing system with a lift pin mechanism, in one implementation.

FIG. 3 illustrates a simplified block diagram of a portion of a process module with a lift pin mechanism that is used for replacing a consumable part, in one implementation.

FIG. 3A illustrates a simplified block diagram of one embodiment of a top ring used in the process module.

FIG. 3B illustrates a simplified block diagram of one embodiment of a mid ring used in the process module.

FIGS. 3C and 3D illustrate simplified block diagram of example lift pins used in the process module to lift the top ring and the mid ring, in different embodiments.

FIGS. 4A-4F illustrate operation flow sequence for separately removing/replacing consumable parts, such as a top ring and a mid ring, used in a process module, in accordance with one implementation.

FIGS. 5A-5F illustrate various stages of movement of the consumable parts (e.g., top ring and mid ring) as they are removed separately using a lift pin mechanism employed within a process module, in one implementation.

FIGS. 5G-5K illustrate various stages of movement of the consumable parts (e.g., top ring and mid ring) as they are removed separately using a lift pin mechanism employed within a process module, in an alternate implementation.

FIGS. 6A-6G illustrate operation flow sequence for separately removing/replacing consumable parts, such as a top ring and a mid ring, used in a process module, in accordance with one implementation.

FIG. 7A illustrates a perspective view of a first embodiment of a top ring used in the process module that is replaceable, in accordance with one implementation.

FIG. 7B illustrates a top view of a top surface of the first embodiment of the top ring used in the process module, in accordance with one implementation.

FIG. 7C illustrates a top view of a bottom surface of the first embodiment of the top ring used in the process module, in accordance with one implementation.

FIG. 7D illustrates a side view of a first embodiment of the top ring used in the process module, in accordance with one implementation.

FIG. 7E illustrates a cross-sectional view of the first embodiment of the top ring used in the process module, in accordance with one implementation.

FIG. 7F illustrates an expanded view of an edge of the first embodiment of the top ring used in the process module, in accordance with one implementation.

FIG. 8A illustrates a perspective view of a first embodiment of a mid ring used in the process module, in accordance with one implementation.

FIG. 8B illustrates a top view of a top surface of the first embodiment of the mid ring used in the process module, in accordance with one implementation.

FIG. 8C illustrates a top view of a bottom surface of the first embodiment of the top ring used in the process module, in accordance with one implementation.

FIG. 8D illustrates a side view of a first embodiment of the mid ring used in the process module, in accordance with one implementation.

FIG. 8E illustrates a cross-sectional view of the first embodiment of the mid ring used in the process module, in accordance with one implementation.

FIG. 8F illustrates an expanded view of a top mid surface of the first embodiment of the mid ring used in the process module, in accordance with one implementation.

FIG. 8G illustrates an expanded view of an edge of the bottom surface of the first embodiment of the mid ring used in the process module, in accordance with one implementation.

FIG. 8H illustrates a top view of a bottom surface of the first embodiment of the mid ring used in the process module, in accordance with one implementation.

FIG. 9A illustrates a perspective view of a second embodiment of a top ring used in the process module that is replaceable, in accordance with one implementation.

FIG. 9B illustrates a top view of a top surface of the second embodiment of the top ring used in the process module, in accordance with one implementation.

FIG. 9C illustrates a top view of a bottom surface of the second embodiment of the top ring used in the process module, in accordance with one implementation.

FIG. 9D illustrates a side view of the second embodiment of the top ring used in the process module, in accordance with one implementation.

FIG. 9E illustrates a cross-sectional view of the second embodiment of the top ring used in the process module, in accordance with one implementation.

FIG. 9F illustrates an expanded view of an edge of the second embodiment of the top ring used in the process module, in accordance with one implementation.

FIG. 10A illustrates a perspective view of a second embodiment of a mid ring used in the process module, in accordance with one implementation.

FIG. 10B illustrates a top view of a top surface of the second embodiment of the mid ring used in the process module, in accordance with one implementation.

FIG. 10C illustrates a top view of a bottom surface of the second embodiment of the mid ring used in the process module, in accordance with one implementation.

FIG. 10D illustrates a side view of the second embodiment of the mid ring used in the process module, in accordance with one implementation.

FIG. 10E illustrates a cross-section view of the second embodiment of the mid ring used in the process module, in accordance with one implementation.

FIG. 10F illustrates an expanded view of an edge of the second embodiment of the mid ring used in the process module, in accordance with one implementation.

FIG. 11A illustrates a perspective view of the first embodiment of the top ring used in the process module, in accordance with one implementation.

FIG. 11B illustrates a top view of a top surface of the first embodiment of the top ring used in the process module, in accordance with one implementation.

FIG. 11C illustrates a top view of a bottom surface of the first embodiment of the top ring used in the process module, in accordance with one implementation.

FIG. 11D illustrates a side view of the first embodiment of the top ring used in the process module, in accordance with one implementation.

FIG. 11E illustrates a cross-sectional view of the first embodiment of the top ring used in the process module, in accordance with one implementation.

FIG. 12A illustrates a perspective view of the first embodiment of the mid ring used in the process module, in accordance with one implementation.

FIG. 12B illustrates a top view of a top surface of the first embodiment of the mid ring used in the process module, in accordance with one implementation.

FIG. 12C illustrates a top view of a bottom surface of the first embodiment of the mid ring used in the process module, in accordance with one implementation.

FIG. 12D illustrates a side view of the first embodiment of the mid ring used in the process module, in accordance with one implementation.

FIG. 12E illustrates a cross-sectional view of the first embodiment of the mid ring used in the process module, in accordance with one implementation.

FIG. 13 illustrates a control module (i.e., a controller) for controlling various aspects of a cluster tool, in accordance with one embodiment.

### DESCRIPTION

Embodiments of the disclosure define a lift pin mechanism within a process module of a substrate processing system that is used to process a semiconductor substrate. The lift pin mechanism is used to replace a consumable part, such as a top ring (i.e., an edge ring), a mid ring, that is disposed adjacent to the semiconductor substrate within the process module. The substrate processing system includes one or more process modules that are used to perform process operations on a semiconductor substrate. Some of the process operations that can be performed in the different process modules include a cleaning operation, a deposition, an etching operation, a rinsing operation, a drying operation, etc. A ring storage station is mounted to the substrate processing system and is used to deliver consumable part, such as a top ring, during replacement of the consumable part in the one or more process module. The consumable part, disposed immediately adjacent to a substrate received in a process module, is exposed to the harsh chemistries in the process module. As a result, the consumable part gets damaged due to constant exposure and is promptly replaced using the lift pin mechanism implemented in the substrate processing system. The replacement of the consumable part is performed in a controlled manner so as to avoid any risk of contamination to the components of the process module or the substrate processing system.

The lift pin mechanism employed in a process module is used to provide access to a used and damaged consumable part, and a robot available within the substrate processing system is used to retrieve the used consumable part from the process module and replace with a new consumable part. In some implementations, in addition to replacing the consumable part, such as a top ring, additional consumable part, such as a mid ring may also be replaced using the lift pin mechanism used for replacing the top ring. The mid ring, disposed immediately below the top ring, may be exposed to some of the contaminants that are generated from the harsh chemicals in the process chamber. Such contaminants may make their way onto a top surface of the mid ring during operation of the process module (e.g., during tuning of the top ring). The contaminants may damage the top surface of the mid ring or may deposit on the top surface making the top surface uneven. The uneven top surface may result in sub-optimal mating of the top ring to the mid ring, which can lead to further damage due to additional contaminants making its way to the surface of the mid ring. As a result, the mid ring may have to be replaced from time to time so as to provide reliable support to the top ring and to prevent damage to underlying hardware components. Due to its location below the top ring, the mid ring may need to be replaced less frequently than the top ring. For instance, the top ring may need to be replaced after exposing the top ring for about 150 to about 300 radio frequency (RF) hours while the mid ring may have to be replaced after about 750 to about 1500 RF hours. Irrespective of how frequently the mid ring needs to be replaced, the various implementations of the lift pin mechanism of the process module described herein provide ways to replace the mid ring in a manner similar to the replacement of the top ring.

Traditional design of a substrate processing system required the substrate processing system to be opened in order to access and replace the consumable part, such as the top ring, within a process module. Opening of the substrate processing system required taking the substrate processing system offline and purging the substrate processing system to atmospheric condition to allow access to the process modules. Once the substrate processing system is opened, a trained technician would manually remove and replace the consumable part from a process module. Upon replacement of the consumable part, the substrate processing system had to be conditioned so that the semiconductor substrate can be processed. Since the semiconductor substrates are valuable products, extreme care has to be taken when conditioning the substrate processing system. The conditioning would require cleaning the substrate processing system, pumping the substrate processing system to vacuum, conditioning the substrate processing system and qualifying the substrate processing system using test runs. Each of these steps requires considerable time and effort. In addition to the time required at every step to condition the substrate processing system, additional delays may be experienced when problems are encountered at one or more of the steps during the conditioning of the substrate processing system.

Some of the problems commonly encountered during the conditioning of the substrate processing system may include misalignment of the consumable part during replacement, damage to the new consumable part when replacing a damaged or used consumable part, damage to other hardware components in the process module during retrieval or replacement of the consumable part, substrate processing system not achieving vacuum after pumping, substrate processing system not achieving process performance, etc. Based on the severity of each problem, additional time and effort may have to be expended, further contributing to delay of bringing the substrate processing system online, directly impacting the profit margin for a manufacturer.

Additionally, most of the focus in the traditional process was to replace top rings (i.e., edge rings) and was not directed toward replacing a mid ring. As the mid ring is disposed below the top ring, it was deemed that replacing the top ring was sufficient to provide optimal processing conditions and that replacing the mid ring was not necessary. However, as newer designs of the top ring allow the top ring to be tuned (i.e., by raising the top ring), the top surface of the mid ring is getting damaged due to contaminants from the process module making their way to the top surface of the mid ring. As a result, it is desirable to replace the mid ring from time to time to allow the top ring to have a reliable surface to rest on when received in the process module. In the various implementations described throughout this application, the mid ring is a replaceable component and the top ring is a tunable and replaceable component.

The lift pin mechanism of the process module provides the capability to replace the top ring as well as the mid ring. The lift pin mechanism is configured to raise both the top and the mid rings so that an end effector of a robot within the substrate processing system can reach in and retrieve the top and the mid rings. In some implementations, the top and the mid rings are moved separately so that the end effector of the robot can retrieve and replace the top ring and the mid ring one at a time. Alternately, the lift pin mechanism allows the top and the mid rings to be moved simultaneously in a manner that allows the top ring to be removed first and the mid ring removed next. In yet other implementations, the lift pin mechanism may move both the top and the mid rings together and the end effector (i.e., arm) of the robot is designed to remove both of the rings together.

In some implementations, the top ring is designed to include a set of grooves (e.g., v-shaped or u-shaped grooves) on an underside surface to allow the top ring to properly align with the lift pins of the process module. These grooves provide “anti-walk” feature, as the grooves are engaged by the lift pins and the top ring is held in place, thereby preventing the top ring from “walking” or sliding. The underside groove feature of the top ring and the use of robot ensure minimal damage to the hardware components of the process module and to the top ring during replacement of the top ring. Further, timely replacement of the consumable parts in a controlled manner reduces the amount of time required to condition the substrate processing system, thereby increasing quality and yield of semiconductor components defined on the semiconductor substrate.

With the general understanding of the inventive implementations, details of specific implementations will be discussed with reference to the various drawings.

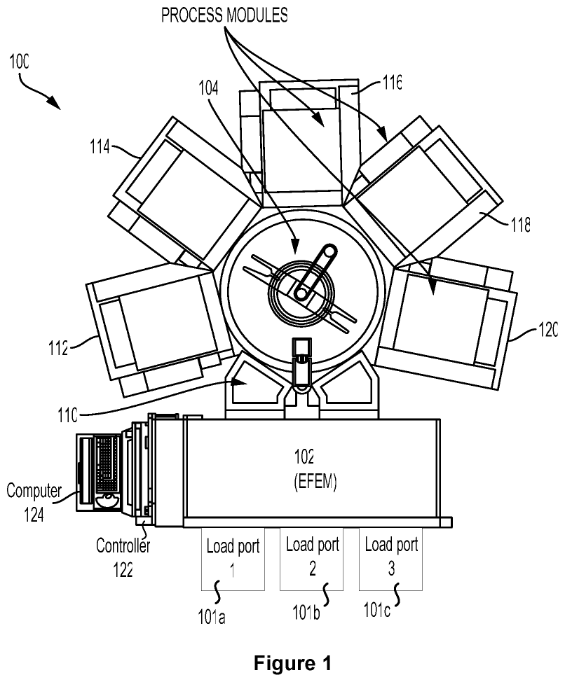

FIG. 1 illustrates a simplified schematic diagram of a sample substrate processing system 100 used to process a semiconductor substrate in which the lift pin mechanism described herein is implemented. The substrate processing system 100 includes a plurality of modules to allow the semiconductor substrate to be processed in a controlled environment. For example, the substrate processing system 100 shown in the figure includes an equipment front end module (EFEM) 102, a common vacuum transfer module (VTM) 104 and one or more process modules 112-120. A first side of the EFEM 102 includes one or more load ports (e.g., 101a through 101c) on which one or more wafer stations (i.e., substrate storage stations) are received. The EFEM 102 is operated under ambient (i.e., atmospheric) condition, thereby allowing a semiconductor substrate to be brought in from a wafer station into the integrated substrate processing system 100 for processing, and for returning the semiconductor substrate, after processing. The EFEM 102 may include a robot (not shown) to move the semiconductor substrate from the wafer station to the VTM 104. The robot may be part of a dry robot as the EFEM 102 is maintained at atmospheric condition.

In some implementations, in addition to loadports 101a-101c for receiving wafer stations, one or more additional loadports may be defined to receive a ring storage station (not shown). The ring storage station is configured to receive and store consumable parts, such as top rings (also referred to herein as “edge ring” as it is disposed adjacent to an outer edge of the substrate within the process module) and mid rings. The loadports to receive ring storage station may be defined on the same side of the EFEM as the loadports 101a-101c or on a different side of the EFEM 102. In alternate implementations, one or more of the loadports 101a-101c may be configured to receive ring storage station while the remaining loadports may be used to receive the wafer station(s).

The VTM 104 is operated under vacuum so as to minimize exposure of the semiconductor substrate surface to atmospheric air as the semiconductor substrate is moved from one process module into another. Since, the VTM 104 is operating under vacuum and the EFEM 102 is operating at Atmospheric condition, one or more loadlock chambers 110 are interfaced between the EFEM 102 and the VTM 104. The loadlock chamber 110 provides a controlled interface to allow the transfer of the semiconductor substrate from the wafer storage through the EFEM 102 to the VTM 104. In this embodiment, the robot within the EFEM 102 is used to deposit the semiconductor substrate into the loadlock chamber 110. A separate robot provided within the VTM 104 is used to retrieve the semiconductor substrate from the loadlock chamber 110 and transfer the semiconductor substrate into and out of process module (112-120). Due to its location, the loadlock chamber, in some embodiments, is also referred to as an “interfacing chamber” or an “airlock”. The loadlock chambers (i.e., airlocks) 110 may be selectively maintained in ambient condition or vacuum. For example, when the substrate is being moved between the wafer station and the airlock 110 via the EFEM 102, the airlock is maintained in ambient condition and when the wafer is being moved between the airlock 110 and the VTM 104, the airlock 110 is maintained in vacuum. Similar process may be used when transporting a consumable part between a ring storage station and the process module.

In some implementations, a load port to receive the ring storage station may be defined on a side of the EFEM where the airlock 110 is defined. In such implementations, the load port to receive a ring storage station may be defined above the airlock. The location of the airlock is not restricted to the sides or location noted herein but could also be located on a different side of the EFEM or below the airlock, etc.

One or more process modules 112-120 are integrated with the VTM 104 so as to allow the semiconductor substrate to move from one process module to another process module in a controlled environment (i.e., without breaking vacuum) maintained by the VTM 104. In some embodiments, the process modules 112-120 may be distributed uniformly around the VTM 104 and used to perform distinct process operations. Some of the process operations that can be carried out using the process modules 112-120 include etch operation, rinsing, cleaning, drying operation, plasma operation, deposition operation, plating operation, etc. By way of example, process module 112 may be used to perform a deposition operation, process module 114 may be used to perform a cleaning operation, process module 116 may be used to perform a second deposition operation, process module 118 may be used to perform an etch or removal operation, and so on. The VTM 104 with the controlled environment allows the semiconductor substrate to be transferred into and out of the process modules 112-120 without risk of contamination and the robot within the VTM 104 assists in transferring the semiconductor substrate into and out of the various process modules 112-120 that are integrated with the VTM 104.

The integrated substrate processing system of FIG. 1 can also be used in replacing consumable parts, such as a top ring and a mid ring used within a process module. The replacement of the consumable part is also conducted in controlled environment thereby minimizing amount of time required for conditioning the substrate processing system after replacement of the consumable part to begin processing the substrates, while ensuring the processing environment does not get contaminated during replacement of the consumable part. In the implementation illustrated in FIG. 1, the ring storage station (not shown) is mounted to a load port defined on one side of the EFEM 102.

In alternate implementation, the ring storage station may be mounted to any one of the process modules 112-120 or to the VTM 104 of the substrate processing system. In the implementation where the ring storage station is coupled to one of the process modules 112-120 or the VTM 104, the ring storage station 108 includes a mechanism, such as a pump mechanism, (not shown) to pump the ring storage station so as to maintain it at vacuum.

An isolation valve may be provided as an interface between the ring storage station and the EFEM, when the ring storage station is coupled to a side of the EFEM. The isolation valve is used to isolate the ring storage station. The isolation of the ring storage station may be useful during loading of the consumable parts onto the ring storage station. Similarly, isolation valve(s) may be used to interface between the ring storage station and the process module or the VTM 104, when the ring storage station is coupled directly to the process module or the VTM 104. Operation of the isolation valve is controlled to allow access to the consumable part in the process module and the ring storage station.

The ring storage station is a moveable, modular unit that is designed to be temporarily mounted to a module of the substrate processing system to complete the required operation of replacing the consumable part, such as the top ring (i.e., edge ring), or the mid ring, and dismounted once the required operation at the process module is completed. The dismounted ring storage station is either retracted or moved to a different module to proceed with the required operation of replacing the consumable part at a second process module.

The ring storage station includes a part buffer with a plurality of compartments for receiving and holding the consumable parts. Separate set of compartments may be defined in the ring storage station to store used consumable parts that are retrieved from a process module, and new consumable parts that are to be delivered to the process module. In one embodiment, an opening in the ring storage station and the size of the isolation valve defined at one or each of the modules (e.g., EFEM, airlocks, or process module) are designed to allow the movement of the consumable part into and out of the ring storage station.

Due to proximity of the consumable part to the semiconductor substrate in the process module and its continuous exposure to the harsh process conditions used during processing of the semiconductor substrate, the consumable part needs to be closely monitored and promptly replaced when the damage to the consumable part exceeds a predefined threshold level. In some implementations, the consumable part that is used in the process module discussed herein is a top ring (also referred to herein as an edge ring) that is tunable and/or replaceable. In addition to the top ring being a replaceable consumable part, in some implementations, a mid ring that is defined below the top ring within the process module may also need to be replaced. The mid ring, in these implementations, is a replaceable hardware component.

For example, in an etch process module, a top ring is disposed adjacent to the semiconductor substrate mounted on a chuck assembly to extend the process region of the semiconductor substrate. During the etching operation, the top ring is exposed to the ion bombardment from the plasma that is used to form features on a surface of the semiconductor substrate. For instance, during the etching operation, ions from the plasma hit the semiconductor substrate surface at an angle that is perpendicular to a plasma sheath formed in a process region defined above the semiconductor substrate, received in the process module. Over a course of time, as a result of continuous exposure to the plasma, a top surface of the top ring gets damaged. When layers of the top ring wear away due to ion bombardment, the edge of the semiconductor substrate is exposed causing the plasma sheath to roll along a contour of the semiconductor substrate edge. Consequently, the ions hitting the semiconductor substrate surface follow the contour of the plasma sheath thereby causing tilt features to be formed toward the edge of the semiconductor substrate surface. These tilt features would affect the overall yield of the semiconductor components formed on the semiconductor substrate.

To improve the yield, reduce edge exclusion region, and to avoid damage to any underlying components, the top ring is tuned by moving the top ring up so as to make the top surface of the top ring coplanar with the top surface of the substrate, when the surface is received for processing. An amount of tuning of the top ring is based on a thickness of the top ring and the amount of damage experienced at the top surface of the top ring. When the tuning of the top ring has exceeded a threshold level, the top ring needs to be promptly replaced. Further, when a damage (e.g., due to tuning of the top ring, due to contaminants generated within the process module, etc.) to the mid ring exceeds the threshold level, the mid ring also needs to be replaced to improve the yield and to prevent damage to the underlying hardware components. The replacement of the mid ring is carried out less frequently than the top ring.

After removing the damaged or used top ring and the mid ring from the process module, the robot of the EFEM 102 is used to transport a new top ring and a new mid ring from the ring storage station to the airlock 110 and the dedicated robot of the VTM is used to transport the new top ring and the new mid ring from the airlock 110 to the process module. Although some of the implementations are discussed herein with reference to the ring storage station being coupled to a side of the EFEM 102, the teachings can be extended to other implementations where the ring storage station is coupled to different modules (process modules 112-120 or VTM 104) of the substrate processing system 100.

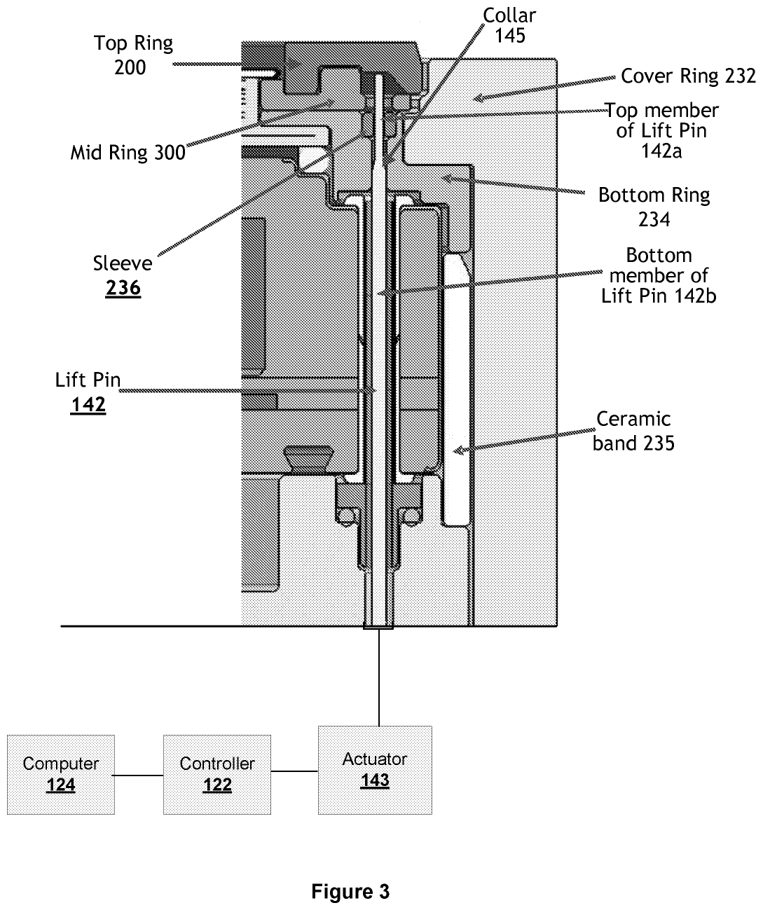

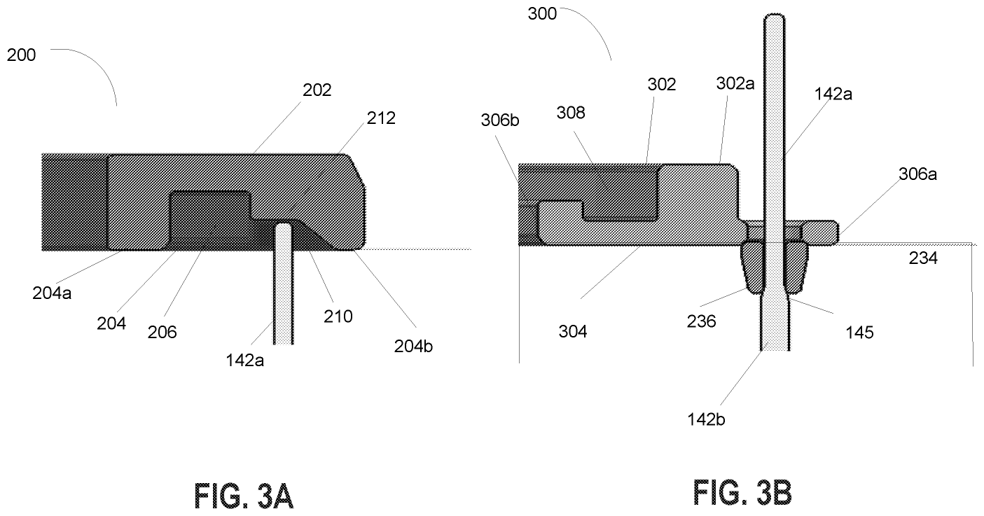

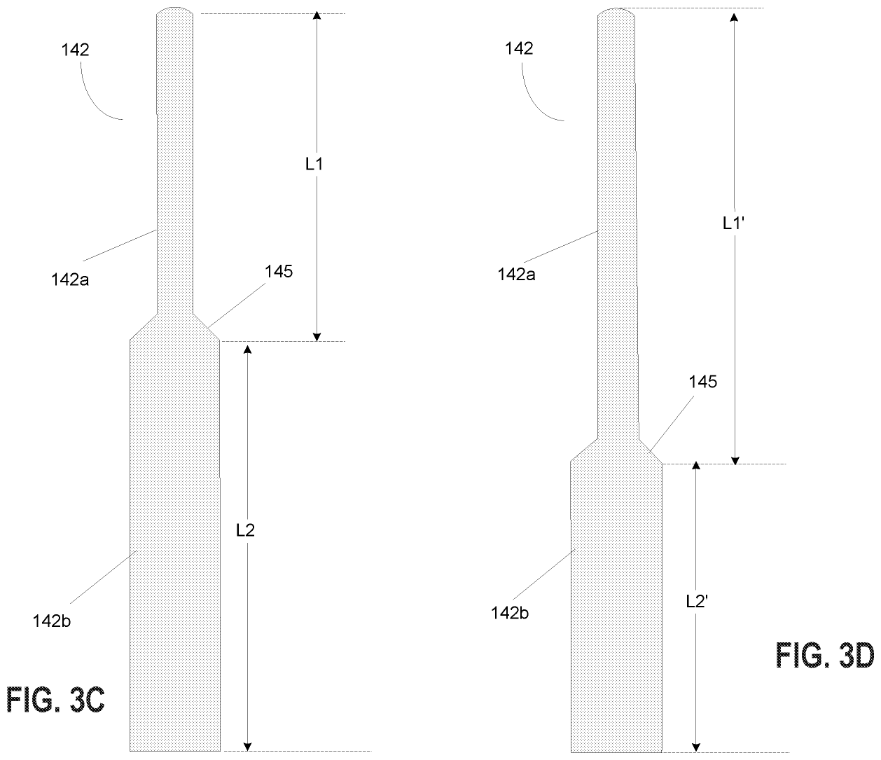

The top ring and the mid ring may each be stored in separate ring storage stations and provided as and when the top ring and the mid ring need to be replaced. A lift pin mechanism (not shown) within the process module 118 provides access to the consumable part. The different parts and functionality of the lift pin mechanism will be discussed in more detail with reference to FIG. 3.

Access to the ring storage station and the process module is coordinated using the different isolation valves and/or gates disposed between the different modules and between the EFEM and the ring storage station. For example, in one implementation, isolation valves and/or gates disposed between the EFEM and the ring storage station and between the VTM 104 and the one or more of the process modules 112-120, the robots of the EFEM 102 and the VTM 104, and the lift pin mechanism of the one or more process modules may all be operatively connected to a controller 122. The controller 122 may be a computer or may be communicatively connected to a computer 124 that can be used to provide input to coordinate operation of the isolation valves and/or gates, the airlocks, movement of the robots of the EFEM and the VTM, and the lift pin mechanism of the process module during retrieval and replacement of the consumable part.

The isolation valve defined between the ring storage station and the El-BM 102 may be used to isolate the ring storage station so that consumable parts may be loaded onto the ring storage station without affecting the processing of the substrate within the substrate processing system. Similarly, a second isolation valve defined between the VTM 104 of the substrate processing system 100 and a process module (112-120) where the consumable part needs to be replaced, is used to isolate the process module from the rest of the substrate processing system 100 so that the replacement of the consumable part within the process module can be easily carried out without affecting operation of other process modules of the substrate processing system 100. Providing the second isolation valve allows specific one of the process modules (any one of 112-120) to be taken off-line instead of the whole substrate processing system 100, while the remainder of the process modules (112-120) within the substrate processing system 100 may be allowed to continue processing the semiconductor substrate. Further, as only a specific process module (e.g., any one of 112-120) is brought off-line for replacing the consumable part(s), it would take considerably less time to restore the process module (112-120) and the substrate processing system 100 to a fully operational state. As a result, time taken for conditioning and qualifying operation of the substrate processing system 100 is much shorter.

In some implementations, when the consumable part, such as the top ring and/or the mid ring, needs to be replaced in more than one process module, the operation of the robots and the corresponding isolation valves within the substrate processing system 100 may be coordinated so that the consumable part may be replaced in a sequential manner In such embodiments, the time taken for replacing the consumable parts in a plurality of modules may be much shorter as the ring storage station and the process module(s) are selectively isolated, thereby allowing the remaining modules to continue with the substrate processing operations.

The various implementations discussed with reference to FIG. 1 allow the ring storage station to be mounted temporarily to the EFEM 102 when a consumable part in the process module (112-120) needs to be replaced, and retracted when the replacement of the consumable part is completed. The ring storage station includes a part buffer with a plurality of compartments for receiving and storing the new and used consumable parts. In a first implementation, the compartments of the ring storage station are used to store new and used top rings and mid rings together. Alternately, in a second implementation, the part buffer of the ring storage station includes two distinct holding areas with a first holding area configured for holding the used consumable parts (i.e., top ring and the mid rings) and a second holding area for holding the new consumable parts (both the top and the mid rings). In a third implementation, a first ring storage station may be used to hold only the new consumable parts with distinct holding areas for holding the new top rings separately from the new mid rings, and a second ring storage station may be used to hold only the used consumable parts with distinct holding areas for holding the used top rings separately from the used mid rings. In yet another implementation, a first distinct holding area may be used to store the new top ring, a second distinct holding area may be used to store the new mid rings, a third distinct holding area may be used to store the used top rings, and a fourth distinct holding area may be used to store the used mid rings, with the areas storing the new rings separated from the areas storing the used rings using a separator plate. Based on how the ring storage stations are configured, appropriate ring storage stations may be coupled to the EFEM when the mid ring and/or the top ring needs to be replaced.

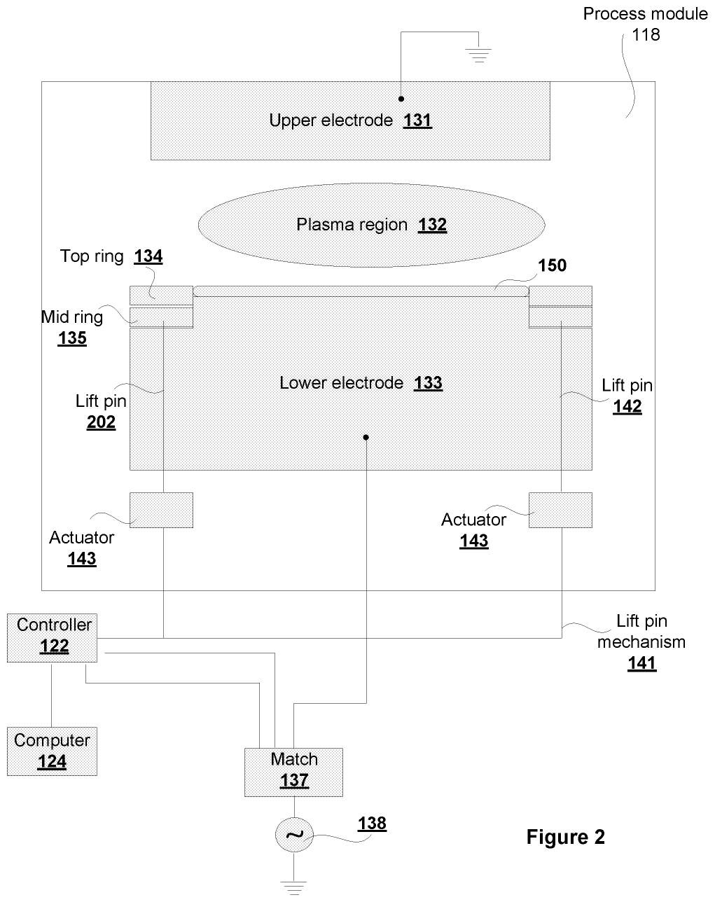

FIG. 2 illustrates a simplified block diagram of a process module within which a lift pin mechanism is used to provide access to the consumable part that needs to be replaced, in one implementation. The process module 118, for example, may be a process etch module in which the process chemistry (i.e., gas chemistry) is provided to generate plasma. The process module 118 includes an upper electrode 131 that may be used to provide process chemistry to a plasma region 132 defined in the process module 118. In the example implementation illustrated in FIG. 2, the upper electrode 131 is electrically grounded. The upper electrode 131 may be a showerhead with a plurality of outlets distributed along a horizontal plane and configured to supply process chemistry to the plasma region 132.

The process module 118 also includes a lower electrode 133. The lower electrode 133 is configured to receive a semiconductor substrate 150 for processing. In one implementation, the lower electrode 133 is an electrostatic chuck (ESC). In another implementation, the lower electrode is a pedestal. In the implementation of FIG. 2, the lower electrode 133 is coupled to a power source to provide power to generate plasma in the plasma region 132. In some implementations, the power source may be a RF power source 138 that is connected to the lower electrode 133 through a match network 137. In an alternate implementation, the upper electrode 131 is connected to a power source through a match network (not shown), and the lower electrode 133 is electrically grounded.

The process module 118 includes a lift pin mechanism 141 to enable the consumable part (i.e., top ring 200 and mid ring 300) to be moved from an installed position to a raised position. The lift pin mechanism 141 includes a plurality of lift pins 142 and actuators 143, which when activated, contacts and lifts the consumable part to a raised position. In one implementation, an actuator drive (not shown) is connected to the actuators 143 and provides the power to drive the actuators 143. In another implementation, the actuator drive may be integrated with the actuator. The actuator drive may be coupled to the controller 122 to control operation of the lift pin mechanism 141 during replacement of the consumable part. The controller 122, in turn, may be part of a computer 124 or may be communicatively connected to a computer 124. The computer 124 is used to provide inputs to control operation of the lift pin mechanism, when the consumable part needs to be replaced. The lift pin mechanism 141 will be discussed in more detail with reference to FIG. 3.

After the consumable part has been replaced, the process module 118 may be conditioned before returning the process module 118 to active operation, in some implementations. The conditioning operation will take a shorter time as the replacement of the consumable part (e.g., top ring 200 and mid ring 300) was carried out in a controlled manner.

FIG. 3 illustrates an example embodiment of different components of a lower electrode used in one or more process modules (112-120) of a substrate processing system 100 where a lift pin mechanism 141 is disposed. The lift pin mechanism 141 provides access to a consumable part during a replacement operation by moving the consumable part out to a replacement position. The lower electrode includes a plurality of components and only specific components surrounding the lift pin mechanism 141 will be discussed with reference to FIG. 3, although other components may be used during processing of the semiconductor substrate. As shown, a top ring 200 is disposed immediately adjacent to a wafer receiving component of the lower electrode, such that a top surface of the top ring 200 is co-planar with a top surface of the substrate 150, when the substrate 150 is received on the lower electrode 133. The lower electrode 133, as mentioned earlier, may be an electrostatic chuck (ESC) or a pedestal, and the wafer receiving component may be a top surface of the ESC or the pedestal. The top ring 200, in some implementations, is made of quartz material. However, the top ring 200 is not restricted to quartz material and other material can be used so long as the functionality of the top ring 200 is maintained. A mid ring 300 is disposed immediately below the top ring 200 and is aligned with the top ring 200. In some implementations, the mid ring 300 is made of quartz material. In other implementations, the mid ring 300 is made of silicon carbide material. It should be noted that the material for the mid ring 300 is not restricted to quartz or silicon carbide but can include other materials so long as the functionality of the mid ring is preserved.

The top ring 200 and the mid ring 300 are defined adjacent to an outer sidewall of the wafer receiving component of the ESC/pedestal. In some implementations, the wafer receiving surface of the ESC, for example, is designed such that the substrate received on the top surface extends beyond an outer edge of the ESC. In these implementations, a portion of the mid ring 300 is disposed adjacent to the outer sidewall and below the portion of the substrate that extends from the outer edge of the ESC. In the example implementation of FIG. 3, a top surface of the mid ring and a bottom surface of the top ring are contoured and not flat. Details of the top ring 200 and the mid ring 300 will now be described with reference to FIGS. 3A and 3B, respectively.

FIG. 3A illustrates a simplified block diagram of a first embodiment of a top ring used in the process module, in one implementation. The top ring 200 includes a top surface 202 that is planar. The top ring 200 is disposed in the lower electrode such that the top surface 202 of the top ring 200 is co-planar with the top surface of the substrate, when received on the lower electrode 133. A bottom surface 204 of the top ring 200 includes a bottom inner surface 204a that is adjacent to the sidewall of the lower electrode 133, when the top ring 200 is in the installed position, a bottom outer surface 204b that is adjacent to the cover ring 232, and a channel 206 disposed between the bottom inner surface 204a and bottom outer surface 204b and running parallel to the circumference of the top ring 200. A groove 210 is defined adjacent to the channel 206. The groove 210, in some implementations, is a v-shaped groove. In alternate implementations, the groove 210 is a u-shaped groove. The groove 210 is defined such that an open end of the groove 210 opens to the channel 206 and the closed end of the groove 210 is adjacent to the bottom outer surface 204b. The groove 210 provides a reliable contact position 212 for the top member 142a of the lift pin 142 to contact the top ring 200 during movement of the top ring 200 between the installed position and the replacement position.

FIG. 3B illustrates a simplified block diagram of a first embodiment of a mid ring used in the process module, in one implementation. The mid ring 300 referred herein is a middle ring disposed between the top ring 200 and other components of the lower electrode, such as the bottom ring 234, etc. The mid ring includes a top surface 302 and a bottom surface 304. The bottom surface 304 is planar. The mid ring is disposed immediately above the bottom ring 234 such that the bottom surface 304 is reliably supported on a top surface of the bottom ring. The top surface 302 of the mid ring 300 includes a top mid surface 302a that is disposed between an outer edge 306a and an inner edge 306b of the mid ring, wherein the inner edge 306b of the mid ring 300 is disposed adjacent to the sidewall of the lower electrode. The top mid surface 302a is contoured to match a contour of the channel 206 in the top ring 200. A mating channel 308 is defined between the inner edge 306b and the top mid surface 302a and is contoured to complement the contour of the bottom inner surface 204a of the top ring 200. A pin channel is defined in the mid ring 300 and is sized so as to allow the top member 142a of the lift pin 142 to extend through. The contour on the bottom surface of the top ring 200 is designed to complement the contour on the top surface of the mid ring 300 so that when the top ring 200 is in the installed position, the top ring 200 reliably mates with the mid ring 300 along the contours.

FIGS. 3C and 3D illustrate the different parts of the lift pin 142 used to support the top ring 200 and the mid ring 300 when the top ring 200 and the mid ring 300 have to be raised and lowered within the process module, in different implementations. FIG. 3C illustrates a first embodiment of the lift pin 142. The lift pin 142 is a single unit and includes a top member 142a and a bottom member 142b. The top member 142a is separated from the bottom member 142b by a collar 145. In some implementations, a diameter of the top member 142a of the lift pin 142 is less than a diameter of a channel of the mid ring 300 through which the top member 142a smoothly extends through, which is less than the diameter of the bottom member 142b of the lift pin 142 and the sleeve 236 defined in the bottom ring 234. A length “L1” of the top member 142a is defined in accordance to a distance the top member has to move the top ring 200 in order to place the top ring 200 at the replacement position. A length “L2” of the bottom member 142b is defined in accordance to a distance the bottom member 142b has to move the mid ring 300 in order to place the mid ring 300 at the replacement position.

FIG. 3D illustrates an alternate embodiment of the lift pin, wherein the length L1′ of the top member is greater than L1 of the top member illustrated in FIG. 3C and the length L2′ of the bottom member is greater than L2 of the bottom member illustrated in FIG. 3C.

In one implementation, a length of the top member of each lift pin is defined to be less than a distance between a top surface of the ESC and a replacement position defined by the ring transfer plane (RTP). In some other implementations, the length of the top member is defined to be equal to the distance between the top surface of the ESC and the RTP. In different implementations, the length of the top member is equal to or greater than or less than the length of the bottom member. In some implementations, the lift pins are made of sapphire. However, the material used for the lift pins are not restricted to sapphire but can use other materials without compromising the functionality of the lift pins.

The plurality of lift pins 142 of the lift pin mechanism 141 are configured to move the consumable part (both the top ring 200 and mid ring 300) between an installed position and a raised position so that the consumable part can be accessed by an arm of a robot when the consumable part needs to be replaced. The collar 145 is defined by a chamfer (i.e., a symmetrically disposed sloping transitional edge between the top and the bottom member). In some implementations, the chamfer is defined at about 45° angle. However, the angle of the chamfer is provided as an example and should not be considered restrictive. Other angles may also be considered for defining the chamfer. For example, in some implementations, the angle of the chamfer may be defined to be 30° or 25° or 50° or any other angle value so long as it is symmetrically disposed between the top and the bottom members, 142a, 142b.

The diameter of the top member is smaller than the diameter of the bottom member. The dimensions of the top and the bottom members of the lift pin are designed so that they can easily move through the channels and housing defined in the ESC. In one implementation, the diameter of the top member is about 40 mm and the diameter of the bottom member is about 60 mm with a chamfer defined between the two members. In this implementation, the channels defined in the bottom ring 234 and the mid ring 300 are sized to accommodate the lift pins. For instance, the size of the channel in the bottom ring may be defined to accommodate both the top and the bottom members of the lift pin while the size of the channel defined in the mid ring may be sized to accommodate the top member of the lift pin. In the above example dimensions of the top and the bottom members of the lift pin, the size of the channel defined in the bottom ring may be greater than 60 mm while the size of the channel in the mid ring may be between about 42 mm to about 58 mm or anywhere in-between. The dimensions provided for the top and the bottom members of the lift pins, and for the channels in the bottom and the mid rings are provided as an example and should not be considered restrictive. Other dimensions may also be envisioned for the top and the bottom members and the channels defined in the various rings (e.g., bottom and mid rings) are sized accordingly. It should be noted herein that the channels in the bottom ring and the mid ring are aligned with the lift pins so that the lift pins can easily extend through the respective channels in the bottom and the mid rings.

Referring back to FIG. 3, a cover ring 232 is defined along an outer perimeter of the top ring 200 and the mid ring 300, such that the cover ring 232 is disposed between a lift pin mechanism 141 defined in the lower electrode, and a chamber sidewall (not shown) of the process module. In some implementations, the cover ring 232 is made of insulating material, such as quartz. In other implementations, the material for the cover ring 232 is not restricted to quartz but may include other insulating material(s). In some implementations, a bottom ring 234 is defined immediately below the mid ring 300 and is disposed between a portion of the lift pin mechanism 141 and the cover ring 232. The bottom ring 234 is aligned with the mid ring 300 and the top ring 200. In some implementations, the bottom ring 234 is made of ceramic material. The material for the bottom ring 234 is not restricted to ceramic material and that other material can also be used so long as the functionality of the bottom ring is preserved. A channel is defined in the bottom ring 234 so as to orient vertically and extend from a bottom surface to a top surface of the bottom ring 234 in order to allow the top member 142a and a bottom member 142b of the lift pin 142 to extend through, when the lift pins are engaged. The channel of the bottom ring 234 is defined to align with the vertical channel defined in the mid ring 300. A housing is defined within the bottom ring 234 to accommodate a sleeve 236. The housing surrounds the channel of the bottom ring 234 and extends from a top surface of the bottom ring 234 downward into the body. Dimension (i.e., length, width) of the housing is defined to house the sleeve 236 that is disposed adjacent to and surround the lift pin 142. In some implementation, the sleeve 236 is made of ceramic material. The sleeve 236 is a moveable component and is designed to be lifted from the housing by the lift pin 142. As such, a bottom surface of the housing is defined to rest the sleeve, when the lift pin is retracted, and a top surface of the housing includes an opening that is wide enough to allow the sleeve 236 and the bottom member 142b of the lift pin to extend through.

In some implementations, a band 235 made of ceramic material may be defined immediately below the bottom ring 234 such that the band 235 is disposed below an outer edge portion of the bottom ring 234 such that it is disposed between a second portion of the lift pin mechanism 141 and the cover ring 232. In some implementations, the band 235 is made of elastomer material, such as perfluorelastomer. Additional insulation material may be defined between the lift pin mechanism 141 and the band 235, in some implementations. The rings/bands are provided between the lift pin mechanism 141 and the chamber sidewall (not shown) of the process module chamber so as to insulate the lift pin mechanism 141.

When the lift pin mechanism is engaged to replace the top ring, each of the lift pins is extended out of a lift pin housing defined in the ESC, contact a groove defined in an underside of the top ring 200 and move the top ring to a first height. The first height is defined as a height that positions the top ring at the RTP. The first height, in one implementation, is defined as a distance between the top surface of the ESC and the RTP less the thickness of the thinnest portion of the top ring. In other implementations, the first height is defined to be a distance between the top surface of the top ring, when in the installed position, and the RTP. In some other implementations, the first height is defined to be less than a distance between the top surface of the ESC and the RTP. The RTP is defined as a height defined within the process module to which the top ring, for example, has to be raised so as to provide sufficient space for the arm of the robot to extend its end-effector into the process module, slide under the top ring to support the top ring and move the top ring out of the process module without the top ring or the arm of the robot hitting the chamber walls or any other hardware component of the process module.

When the mid ring is to be replaced, the lift pin is extended further so that the collar between the bottom member and the top member of the lift pin engages with a sleeve 236 defined in the bottom ring 234, and moves the sleeve 236 out of its housing. The sleeve 236 engages with the mid ring 300, and the bottom member of the lift pin with the sleeve 236 and the mid ring 300 continues to move up till the bottom member extends to a second height. The second height is defined to be a height to which the second member of the lift pin has to be moved up in order to raise the mid ring to the RTP. The second height, in some implementations, is defined to be a distance between the RTP and a surface on which the mid ring rests, when the mid ring is in the installed position. In some implementations, the second height is greater than the first height. As a result, the length of the bottom member, in such implementations, may be greater than the length of the top member.

Based on the first height and the second height to which the top and the bottom members of the lift pin 142 are respectfully being moved, the length of the top member may be equal to or greater than or less than the length of the bottom member. The actuators provide sufficient power to the lifts pins to enable the top and the bottom members to move the top ring and the mid ring to the RTP position defined for the process module so as to allow the robot to replace the consumable part—i.e., the mid ring and/or the top ring. Once the top ring has been moved to the RTP (i.e., top ring replacement position), the arm of the robot moves in and removes the used top ring from the process module 118 and replaces the used top ring with a new top ring. After the arm of the robot extends in to the process module to support the top ring and before the arm removes the top ring from process module, the lift pin is at least partially retracted so that the lift pin is not in the way of the arm and the top ring. A used mid ring is replaced with a new mid ring in a similar fashion.

The process of engaging the lift pins can also be used during tuning of the top ring. For tuning the top ring, the lift pin 142 is moved incrementally so that the lift pin carries the top ring to a different height so as to make the top surface of the top ring co-planar with the top surface of the ESC.

The plurality of lift pins 142 may be distributed along a horizontal plane throughout the ESC to allow the lift pins 142 to contact the consumable part at different points and provide kinematic support when moving the consumable part vertically to different heights in the process module. In some implementations, the plurality of lift pins may include a set of three lift pins that may be distributed uniformly along the radial axis so that they are equidistant from one another and are each at a distance from a center that is at least a radius of the top ring. The number of lift pins is not limited to three but could include more than three so long as the lift pins are able to provide kinematic support to the top ring when it is being moved vertically inside the process module.

In some implementations, a plurality of lift pins distributed in the horizontal plane may be grouped into distinct sets, with each set of lift pins being independently operable to provide different functionality. For example, the lift pins are used to tune and to replace a consumable part, such as a top ring, mid ring. The top ring, in this example, is a tunable and replaceable edge ring used in the process module of the substrate processing system and the mid ring (i.e., middle ring) is a replaceable component that is disposed between the top ring and a bottom ring. Accordingly, in one implementation, a first set of lift pins may be used to tune the top ring and a second set of lift pins may be used to replace the top ring and the mid ring. In this implementation, the first set of lift pins may be shorter than the second set of lift pins, as the first set of lift pins are used to raise the top ring to a height defined by a tuning range, which is shorter than a height where the ring transfer plane is defined. Each lift pin is connected to an actuator and the actuators of the plurality of lift pins are connected to an actuator drive that provides the power to activate the lift pins.

In an alternate implementation, the first set of lift pins are used to tune and to replace the top ring, while a second set of lift pins are used to replace a mid ring. In this alternate implementation, the height of the first set of lift pins may be same as the second set of lift pins as both set of lift pins need to raise the top ring and the mid ring from the installed position to the height of the RTP. Alternately, the height of the first set of lift pins used to move the top ring may be smaller than the height of the second set of lift pins used to move the mid ring and the difference in height may be defined by the difference in the thickness of the top ring and the mid ring.

In one example, the first set and the second set of lift pins includes 3 lift pins each, with each of the lift pins from the first set and the second set connected to a corresponding actuator. Thus, a total of 6 actuators may be present, with first 3 actuators connected to the 3 lift pins of the first set, and a second 3 actuators connected to the 3 lift pins of the second set. The lift pins and the corresponding actuators of the first set and the second set are distributed uniformly proximal to an outer edge of the lower electrode and disposed equidistant from one another, such that each actuator and the corresponding lift pin of the first set is disposed 60° apart from a neighboring lift pin, actuator from the second set. The first set of lift pin may be used to tune and remove the top ring and once the top ring is removed, the first set of lift pins are retracted and the second set of lift pins are activated to remove the mid ring.

The tuning of the top ring includes moving the top ring, each time, incrementally up to a different vertical height within the process module using the first set of lift pins so that a top surface of the top ring, after each incremental tuning, is co-planar with a top surface of the substrate received in the process module. The tuning may be done after certain number of etch operations performed in the process module or may be done based on amount of damage incurred at a top surface of the top ring.

The height to which the top ring can be moved during each incremental tuning is defined by the thickness of the top ring remaining, an amount of damage experienced at the top surface of the top ring and a predefined maximum threshold height of tuning. It should be noted herein that the maximum threshold height for tuning the top ring may be defined to be less than a height of the raised position (or replacement position) defined for the process module. The raised position is the maximum height that the lift pins 142 can be moved in order to place the top ring at the RTP so that an arm of a robot can reach into the process module, access the top ring and move it out of the process module. It should be noted herein that RTP to which the top ring is to moved is less than a height at which the top electrode of the process module is disposed. Similarly, the maximum amount of tuning that may be performed for the top ring may be driven by the thickness of the top ring remaining prior to each tuning. If the top ring has undergone tuning a predefined number of times or if the thickness of the top ring deems further tuning would damage the top ring, then it may be considered that maximum tuning has been reached, at which time the top ring has to be replaced.

The second set of lift pins is used for replacing the top ring and is, therefore, configured to lift the top ring to the raised or the replacement position, when activated. The raised or the replacement position is defined as the ring transfer plane as this position provides sufficient clearance space for an arm (i.e., an end-effector) of a robot to extend into the process module, access the top ring and transfer the top ring out of the process module without damaging any hardware component of the process module or the top ring itself.

The lift pins that are used to move the top ring are also be used to replace the mid ring 300 that is disposed below the top ring 200. In the case of replacing the mid ring, only one set of lift pins may be engaged. For instance, the second set of lift pins that was used to replace the top ring may also be used to replace the mid ring.

In one implementation, the lift pins may be used to move both the top and the mid rings (200, 300), simultaneously. In such implementation, the movement of the top ring and the mid ring may be done such that a distance of separation exists between the top ring and the mid ring so as to allow the arm of the robot to reach in and first move the top ring that is in the raised position out of the process module and then move the mid ring 300 to the raised position (i.e., RTP) so that the arm of the robot can reach back in and move the mid ring. In alternate implementations, the lift pins may be used to move the top and the mid rings separately. In yet other implementations, the first set of lift pins may be used to perform tuning and replacing of the top ring 200 and the second set of lift pins may be used to replace the mid ring 300.

The top ring may include a set of grooves (i.e., anti-walking feature) defined on the underside surface for the lift pins to allow the lift pins to engage with so that the top ring can be moved without sliding or moving out of place. The grooves may be v-shaped or alternately u-shaped. In the implementation that uses two distinct set of pins for tuning and replacing the top ring, the first set of lift pins may be slightly offset from the second set of lift pins so that each of the first and second set of lift pins may engage with the groove to provide reliable lifting. The amount of offset between the first set of lift pins and the second set of lift pins is driven by the dimensions of the grooves so that when the lift pins are activated, both the first and the second set of lift pins easily align with the v-groove. In some implementations, the grooves are formed with inclined sidewalls meeting at one end. The aligning with the groove, in such implementations, may include aligning the lift pins in each set so that the lift pins contact some part of the first sidewall or the second sidewall of the v-groove and easily slide into place within the v-groove.

In some implementations, the inclined sidewalls of the grooves meeting at one end to form a sharp tip forming a v-shaped groove. In alternate implementations, the inclined sidewalls of the v-grooves meet at a tip that is rounded (i.e., forming a u-shaped tip instead of a v-shaped tip) so that when the lift pins come in contact with the sidewalls, they slide along the inclined sidewalls and the rounded tip to end inside the u-shaped groove. To provide reliable contact with the v-shaped or u-shaped grooves on the underside surface of the top ring, the offset is defined to be less than a width of the broadest portion of the inclined walls of the v-shaped or u-shaped groove. As the first and the second set of lift pins are offset from one another, the lift pins from the first set may contact a portion of the first inclined sidewall of the anti-walk grooves and the lift pins from the second set may contact a portion of the second inclined sidewall of the anti-walk grooves, with each set of lift pins sliding into place into the v-groove. Each set of the lift pins are activated at different times and this design feature of the top ring provides reliable contact surface of the top ring for both set of the lift pins.

The lift pins 142 of the lift pin mechanism 141 are connected to a plurality of actuators 143. For example, each lift pin 142 may be connected to a distinct actuator 143. In some implementations, the actuators 143 are vacuum-sealed actuators that are outfitted with a corresponding lift pin 142. The actuators 143 are connected to one or more actuator drives (not shown) through which power is provided to drive the actuators of the lift pins. The actuator drive is, in turn, connected to a controller 122 that provides the control signal to activate the lift pins 142. The controller 122 is communicatively connected to a computer 124 through which input is provided to engage the lift pin mechanism 141.

In a disengaged mode, the lift pins 142 stay retracted inside a lift pin housing defined in the lower electrode so that they are not in contact with the consumable part (i.e., top ring 200 or mid ring 300). When a top ring 200 needs to be replaced, the actuators 143 are powered through the actuator drive. Each powered actuator 143 causes the corresponding lift pin 142 to extend out of the lift pin housing through the various channels defined in the bottom ring 234 and the mid ring 300, so as to come in contact with the top ring 200 and move the top ring 200 to a raised position. The top ring 200 is raised by the lift pin by engaging with the v-grooves of the top ring. As the process module (e.g., process module 118) is maintained in a vacuum state, when the top ring 200 is raised, the top ring 200 is raised into a vacuum space defined between the lower electrode (e.g., ESC) and the top electrode. A robot of the VTM 104 coupled to the process module 118, extends an arm with an end effector into the process module 118 and allows it to slide underneath the raised top ring 200. An input may be provided to the computer 124 to generate a signal from the controller 122 to the robot to cause the robot to extend its arm, and to the valve/gate disposed between the process module 118 and the VTM 104 so as to coordinate access to the process module 118. In some embodiments, the end effector attached to the robot is shaped like a spatula allowing the end effector to support the raised top ring. Once the end effector has slid into place to support the top ring, the actuators 143 retract the lift pins 142 into the lift pin housing, causing the top ring 200 to rest on the end effector. The arm of the robot is then retracted back into the VTM 104, bringing the top ring 200 with it. The end effector of the robot of the VTM then places the retrieved used top ring 200 in a compartment within the airlock 110 so that a robot of the EFEM 102 can retrieve the used top ring 200 from the compartment of the airlock 110 to a compartment defined in the ring storage station. A reverse order process occurs when a new top ring 200 is to be provided to the process module (e.g., 118).

The lift pin mechanism of the process module (e.g., 118) is used to properly install the top ring in its location defined in the process module (118) so that the process module (118) and the substrate processing system 100 are operational after replacement of the top ring. To properly install the top ring in its location, the top ring is pre-aligned within the ring storage station prior to moving the top ring to the process module via the EFEM and the airlock. The robots of the EFEM and the VTM maintain the pre-alignment so that when the top ring is received in the process module 118 at the raised position, the pre-aligned top ring aligns with the lift pins enabling the lift pins to engage with the v-grooves and move the top ring from the raised position to the installed position.

In some implementations, in addition to engaging with the v-grooves defined on an underside surface of the top ring, the lift pin mechanism 141 may be used to provide electrostatic clamping to clamp the top ring in position within the process module (e.g., 118) to further ensure that the top ring 200 does not move during lifting or lowering. In these implementations, the lift pin mechanism 141 may be connected to a direct current (DC) power source to allow the DC power to be provided to the lift pins 142 in order to clamp the top ring in position within the process module (e.g., 118). In alternate implementations, the lift pin mechanism may be connected to an air compressor or other compressed pressure source instead of a electrical power source to allow the lift pin mechanism to be operated pneumatically instead of electrically.

The controller 122 may include a vacuum state control (not shown) and a transfer logic (not shown) to facilitate coordinating operation of the various modules and components that are connected to the controller 122. In one implementation, when a top ring is to be replaced in the process module 118, the ring storage station is coupled to the EFEM 102. In response to detecting coupling of the ring storage station at the EFEM 102, a signal may be sent from an isolation valve (not shown) disposed between the EFEM and the ring storage station, to the controller 122. In response to the signal from the isolation valve, the controller 122 coordinates the operation of the robot of the EFEM 102, the pumping of the airlocks, the robot of the VTM 104, the isolation valve/gates disposed between the VTM 104 and the process module 118, and the lift pin mechanism 141 in the process module 118.

For example, in response to the signal from the isolation valve at the EFEM 102, the controller 122 may send a control signal to the lift pin mechanism 141 to activate the actuators 143. The activated actuators 143 power the lift pins 142 so that the lift pins extend out from the lift pin housing through the channels defined in the bottom ring and the mid ring 300 of the lower electrode and contact a bottom surface of the top ring 200. The top ring, as stated earlier, may include a set of v-grooves defined on an underside surface. In some implementations, the top ring may include a channel defined in the bottom surface of the top ring 200 running parallel to a circumference of the bottom surface. The channel may be defined in the middle of the bottom surface. The v-grooves may be distributed uniformly in the bottom surface along a radial plane and be positioned between the outer circumference of the top ring and an outer edge of the channel, and open into the channel defined in the bottom side of the top ring. These v-grooves are aligned with the lift pins so that the lift pins engage with the v-grooves.

In some implementations, a set of three lift pins are provided in the lift pin mechanism to align with a set of three v-grooves defined on the bottom surface of the top ring 200. The number of lift pins and the corresponding v-grooves are not restricted to three but can include additional lift pins/v-grooves so long as they can provide reliable kinematic support to the top ring.

The control signal executes a transfer logic to coordinate movement of the top ring from the process module 118 to a compartment in the ring storage station. For example, the transfer logic is configured to send necessary signals to operate the isolation valve or gate separating the VTM 104 from the process module 118 and to activate the robot of the VTM 104 to retrieve the top ring from the process module 118. The activated robot extends its arm with an end-effector (not shown) into the process module to retrieve the top ring that has been lifted to a raised position by the lift pin mechanism 141. In addition, the transfer logic of the controller 122 may send a vacuum state signal to a vacuum control module to begin the process of pumping the airlock 110 interfaced between the VTM 104 and the EFEM 102, to vacuum. In response to the vacuum state signal received from the transfer logic, the vacuum control module may activate a pump within the airlock 110 to allow the pump to bring the airlock 110 to a vacuum state. Once the airlock 110 has reached a vacuum state, a second signal is sent from the vacuum control module to the transfer logic. The transfer logic then sends a third signal to the robot of the VTM 104 to retrieve the used top ring retrieved from the process module and store in a compartment within the airlock 110. Upon detecting presence of the used consumable part in the airlock 110, a fourth signal may be sent by the transfer logic to pump the airlock 110 to atmospheric condition. Once the atmospheric condition has been reached in the airlock 110, a fifth signal may be sent by the controller 122 to the robot of the EFEM 102 to retrieve the used consumable part from the airlock 110 and move it to a compartment within the ring storage station. A new consumable part is then retrieved from the ring storage station and the process of moving the new consumable part to the process module 118 is carried out in a reverse order.

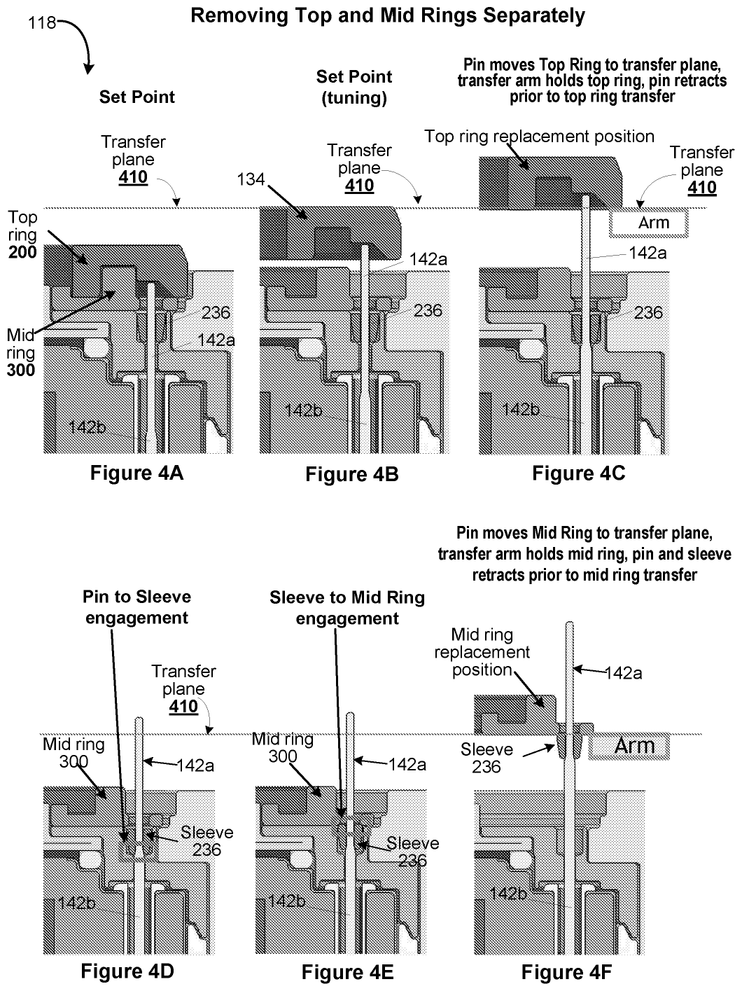

FIGS. 4A-4F illustrate the process of engaging the lift pin mechanism to replace consumable part used in a process module 118, in one implementation. The lift pin mechanism described herein is used for replacing a top ring as well as a mid ring, wherein the top ring is a tunable and replaceable edge ring and the mid ring is a replaceable mid ring. The top ring and the mid ring are replaced separately using the lift pin mechanism.

FIG. 4A illustrates the installed position of both the top ring and the mid ring 300. The contour of the top ring complements the contour of the mid ring so as provide reliable mating when in the installed position. Additionally, a transfer point where the top ring is to be positioned (i.e., ring transfer plane or RTP 410) during replacement, is identified. The lift pin mechanism is activated, causing the lift pin 142 to extend through the channels defined in the bottom ring 234, the mid ring 300, and contact an underside surface of the top ring. The v-grooves, for example, defined on the underside surface of the top ring are aligned such that the lift pin engages with the v-groove to provide reliable support. A cross-section of the process module shown in FIG. 4A shows the lift pin engagement with the v-groove.

FIG. 4B illustrates the movement of the top ring to the replacement position. As shown, the lift pin 142 is in the process of moving the top ring 200 from the installed position to the raised position (i.e., replacement position) defined by the RTP 410. In FIG. 4B, the top member 142a has been fully extended and the bottom member 142b is being extended out of the housing to raise the top ring. FIG. 4C illustrates the replacement position to which the top ring 200 has been moved by the lift pin 142. Responsive to detecting the top ring 200 at the RTP 410, the robot of the VTM 104 extends its arm with the end-effector into the process module and supports the top ring at the RTP 410. The lift pin is then at least partially retracted (not shown). The partial retraction ensures that the lift pin is not in the way of the robot's arm as the robot arm is carrying the top ring out of the process module. After retraction of the lift pin, transfer of the top ring out of the process module is effectuated.

FIG. 4D illustrates the process of replacing the mid ring 300. After the top ring has been moved out of the process module 118, when the mid ring 300 has to be replaced, the lift pin 142 is moved up so that the collar 145 defined by the chamfer engages with the sleeve 236 in the housing defined in the bottom ring 234 (i.e., pin-to-sleeve-engagement). The pin-to-sleeve-engagement wherein the collar 145 has engaged with a bottom surface of the sleeve 236 is shown as a rectangular box in FIG. 4D.

FIG. 4E illustrates a sleeve-to-mid-ring-engagement. As the lift pin continues to be moved up, the engaged sleeve is moved up and out of the housing. During the movement upward, the sleeve 236 engages with the bottom surface of the mid ring 300 to form the sleeve-to-mid-ring-engagement, shown as a rectangular box in FIG. 4E. It should be noted that an opening defined in a bottom portion of the housing for the sleeve 236 is sized to allow only the top and bottom members of the lift pin to move freely in and out, while the top portion of the housing includes an opening that is sized to allow the top and bottom members of the lift pin, as well as, the sleeve 236 to move in and out. Thus, when the sleeve 236 engages with the collar of the lift pin 142, the bottom member of the lift pin moves upward carrying the engaged sleeve 236 with it and when the lift pin is retracted, the sleeve rests in the housing while the bottom member retracts into the lift pin housing.

As the lift pin with the engaged sleeve 236 is moved up, the sleeve 236 balances and moves the mid ring 300 with it. The bottom member of the lift pin with the engaged sleeve 236 moves the mid ring 300 to a height defined by the RTP 410, as shown in FIG. 4F, so that the robot of the VTM can extend its arm, balance the mid ring on it and move the mid ring, once the lift pin has retracted either partially or completely into the lift pin housing.

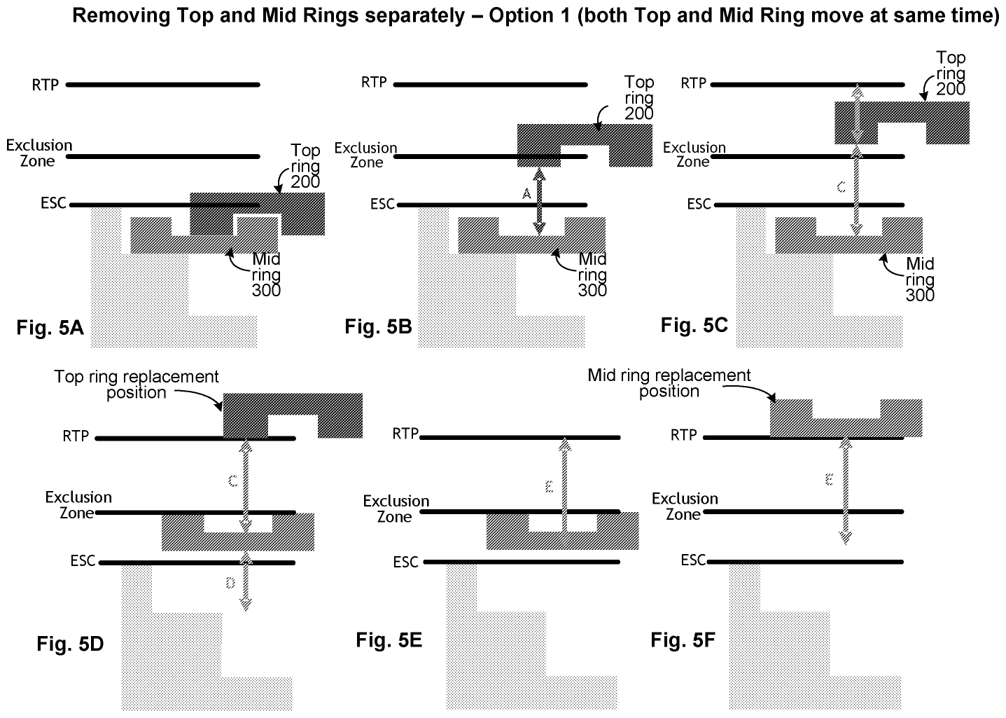

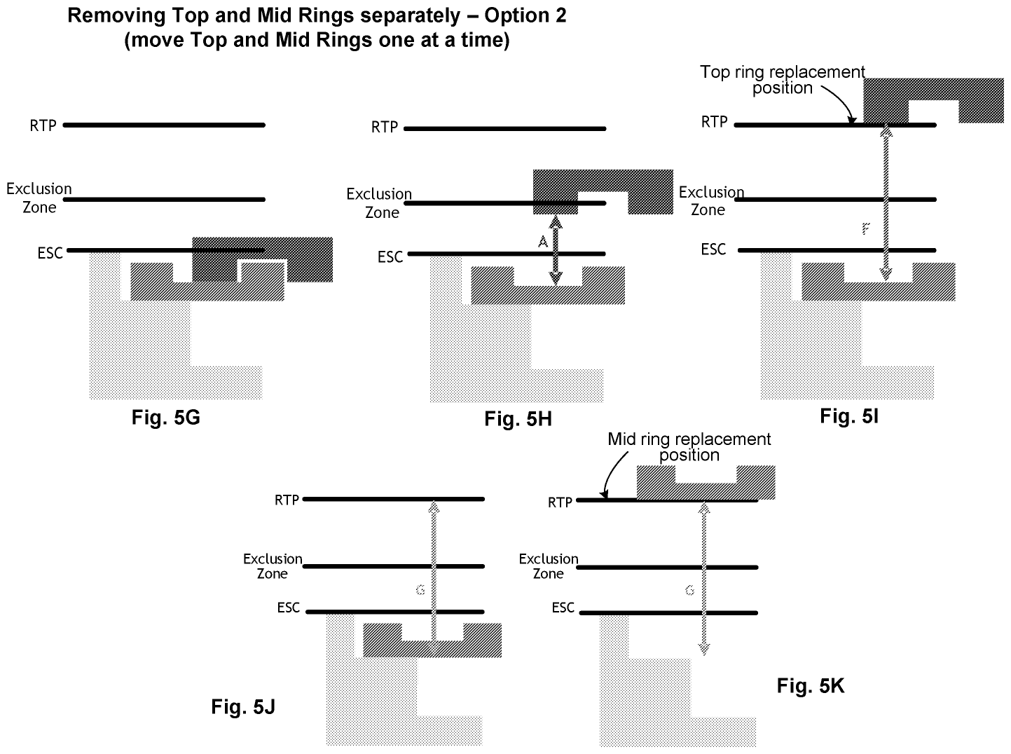

In one implementation, the top ring and the mid ring are moved together but removed separately, one at a time. FIGS. 5A-5F will be described with reference to this implementation. In an alternate implementation, the top ring and the mid ring may be moved separately and removed separately using the lift pin mechanism. FIGS. 5G-5K will be described with reference to this implementation.

FIGS. 5A-5F illustrate the step-by-step process of moving the top ring and the mid ring together but removing them separately. In FIG. 5A, the lift pin mechanism 141 being activated. At this time, the top ring that was in installed position adjacent to a sidewall of the ESC, for example, is moved up by extending the top member of the lift pin from the housing. The top member of the extended lift pin 142 contacts a bottom side of the top ring and starts to move the top ring from the installed position. In FIG. 5A, the top ring has been moved from the installed position that is coplanar to a top surface of the ESC (represented as ESC Cer) to a first height. The top member of the lift pin continues to move the top ring vertically to a second height, represented as “A” in FIG. 5B. In one implementation, the second height represents the tuning range—i.e., a maximum height to which the top ring can be moved during tuning before the top ring needs to be replaced. In this implementation, the height represented by the tuning range A is shown to be less than the height at which an “Exclusion Zone” is defined in the process module. The exclusion zone is defined as an area or region between the top electrode and the bottom electrode of the process module where the end-effector of the robot enters the process module to access the top ring. The second height is shown to be proximate to the exclusion zone.

FIG. 5C illustrates a third height “C” to which the top ring has been moved by the lift pin 142. The third height C is shown to be greater than the height of the exclusion zone and is less than the height of the RTP defined in the process module. As can be seen from FIG. 5C, the lift pin needs to move the top ring an additional height in order for the top ring to reach the height where the RTP is defined. In the example illustrated in FIG. 5C, the third height C is defined as the maximum height to which the top member of the lift pin can be extended before the bottom member engages with the mid ring. FIG. 5D illustrates this concept. As shown in FIG. 5D, as the top member of the lift pin moves the top ring to height C, the bottom member of the lift pin engages with the sleeve 236 and begins to move upward with the engaged sleeve. The lift pin 142 with the engaged sleeve lifts the mid ring 300 from its installed position to a position defined by height “D”. The height D is defined to be a height to which the mid ring has to be moved so that the top ring can be positioned at the RTP 410 (i.e., top ring replacement position). Further, as shown in FIG. 5D, the height to which the mid ring is moved is such that a distance of separation between the top ring and the mid ring is defined by height “C”. This separation distance C is defined so that both the top ring and the mid ring are outside of the exclusion zone in order to allow the robot's arm to extend inside the process module and remove the top ring from the RTP. During removal of the top ring, the lift pin is at least partially retracted and the amount of retraction is at least sufficient to make the lift pin stay out of the exclusion zone so that the removal of the top ring can be carried out unhindered.

Once the top ring is moved and the arm of the robot has been withdrawn from the process chamber, the lift pin continues to be extended so that the mid ring can be moved a height “E”, as shown in FIG. 5E. This allows the mid ring to be moved from below the exclusion zone and be positioned at the RTP (i.e., the mid ring replacement position). FIG. 5F illustrates the height E to which the lift pin was moved to position the mid ring at the RTP. As shown in FIGS. 5D and 5F, the height E that the mid ring was moved is greater than the separation distance C between the mid ring and the top ring. Once the mid ring has been positioned on the RTP, the end-effector of the robot is extended into the process module to support the mid ring. The lift pins are then at least partially retracted to allow the end-effector of the robot to move the mid ring out of the process module. The implementation of FIGS. 5A-5F allows the top ring and the mid ring to be moved together but removed separately. In this implementation, the top member and the bottom member may be of equal length. Alternately, the length of the top member may be different from the length of the bottom member and may be driven by the height to which the top ring and the mid ring have to be raised in order to reach the RTP.

FIGS. 5G-5K illustrates an alternate implementation in which the top ring and the mid ring are moved separately and removed separately. As shown in FIG. 5G, the lift pin mechanism is activated. Accordingly, the top member engages with the bottom surface of the top ring and moves the top ring from the installed position, wherein the top surface of the top ring is co-planar with the top surface of the ESC, to a first height that is higher than the installed position. The lift pin 142 continues to move the top ring from the first height to a second height “A” that is between the exclusion zone and the RTP. As the second height is below the RTP, the lift pin continues to raise the top ring to a third height “F” that allows the top ring to be positioned at the RTP (i.e., top ring replacement position). The height to which the lift pin is extended is defined by the third height F. The third height is before the bottom member of the lift pin engages with the sleeve. Once the top ring has been moved the third height F to the RTP, the arm of the robot of the VTM with the end-effector is extended into the process module so as to support the top ring at the RTP. The lift pin is then at least partially retracted so that the exclusion zone is free to allow the end-effector to move the top ring out of the process module.

After the top ring has been moved out of the process module, the lift pin continues to move the mid ring from the installed position to the replacement position. FIG. 5J illustrates the beginning stage of moving the mid ring. As shown, the mid ring is in an installed position, where it is resting on a portion of the ESC defined adjacent to a sidewall of the ESC, for example. The mid ring has to be moved a height “G” in order to reach the RTP in order for the robot to remove the mid ring from the process module. FIG. 5K illustrates a result of the bottom member of the lift pin with the sleeve moving a height “G”, and the mid ring moving to the RTP defining the mid ring replacement position. Once the mid ring is positioned at the RTP, the end-effector of the robot is used to support the mid ring. The lift pin is at least partially retracted into the lift pin housing, and the end-effector of the robot moves the mid ring out of the process module. A new mid ring and a new top ring are returned to the process module by following a reverse order of the process used in removing the top ring and the mid ring. Specifically, a new mid ring is installed into the process module following which a new top ring is installed.

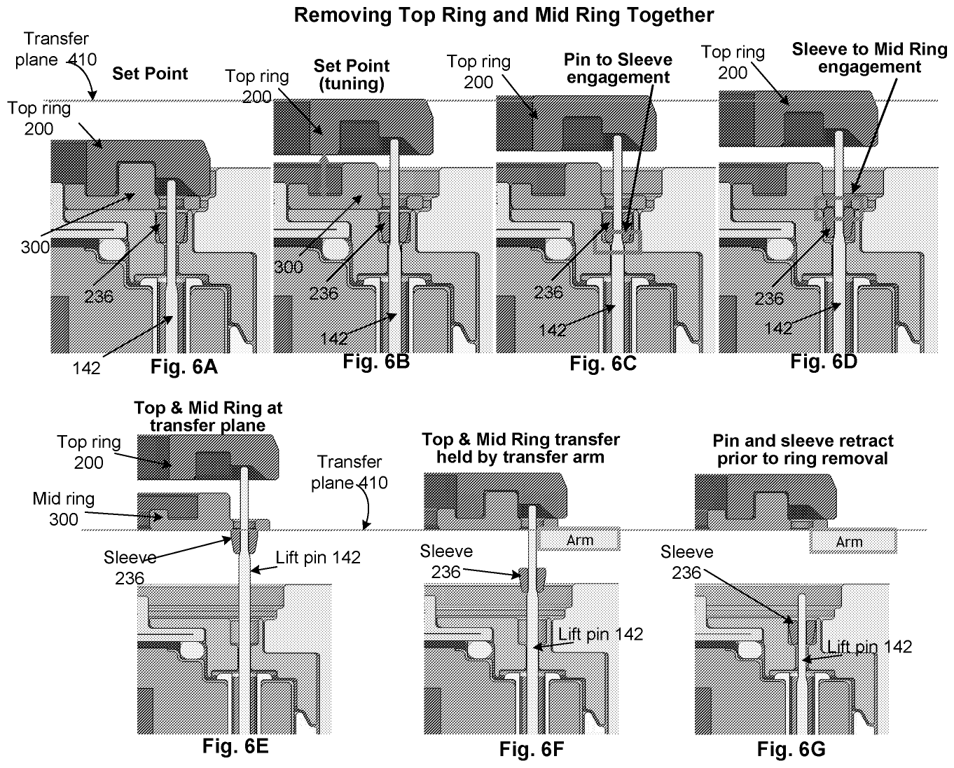

FIGS. 6A-6G illustrate an alternate implementation wherein the top ring and the mid ring are moved and removed together. In this implementation, the lift pin mechanism is activated so that the lift pins can be used to move the top and the mid rings out of the process module and be replaced with a new top ring and new mid ring. FIG. 6A illustrates the first step where a point to which the top ring has to be moved is identified as a ring transfer plane. The lift pin is then engaged so that the top ring is balanced on the lift pins and moved to a first height as shown in FIG. 6B. The first height is below the RTP and may be a height representing an outer limit of the tuning range, at which time further tuning cannot be done and the top ring needs to be replaced. In this stage, the lift pin is engaged so that it moves out of the lift pin housing and through the channels defined in the bottom ring and the mid ring so that the top member can contact and engage with v-groove defined in the bottom surface of the top ring. At this stage, the sleeve remains in the housing of the bottom ring.

FIG. 6C shows the next step wherein the bottom member of the lift pin engages with a sleeve defined in the bottom ring as the lift pin is moved upward. FIG. 6D shows the next step wherein the sleeve engages with a bottom surface of the mid ring. The engagement of the sleeve with the bottom surface of the mid ring is effectuated by moving the lift pin up so that the collar defined between the top member and the bottom member engages and moves the sleeve. FIG. 6E shows the step where the bottom member with the engaged sleeve is used to move the mid ring from the installed position to the RTP. As the mid ring is moved to the RTP, the top ring continues to be maintained at a separation height, wherein the separation height, in one example, may be defined by the tuning range, for example.

Once the mid ring has reached the RTP, the lift pin is partially retracted thereby allowing the top ring to mate with the mid ring at the RTP plane. FIG. 6F illustrates the mating of the top ring with the mid ring to form a combined unit. In response to positioning the mid ring and the top ring at the RTP, a robot of the VTM 104 is activated. The activated robot extends an arm with the end-effector into the process module and supports the top and the mid ring combined unit. As shown in FIG. 6G, responsive to the top and the mid rings being supported on the end-effector, the lift pin and the sleeve retract leaving the end-effector to support the top and mid ring unit and move the unit out of the process module. The sleeve retracts into the housing in the bottom ring and the lift pin retracts into the lift pin housing defined in the lower electrode. The replacement of the used top ring and the used mid ring with a new top ring and new mid ring will follow the reverse process used in removing the used top and used mid rings identified herein. In the implementation illustrated in FIGS. 6A-6G, the end-effector is designed such that it is able to support and move both the top ring and the mid ring simultaneously without unduly straining the end-effector or causing unnecessary bending. The designing of the end-effector may include using a different material or providing additional reinforcements to prevent the end-effector from bending or snapping.

The various implementations described herein provide ways to replace the top ring and the mid ring in an efficient manner without breaking vacuum of the process module so that the process modules can be conditioned faster and returned to active processing in a short time. The geometry of the top ring with the grooves defined on the underside surface along with features of the lift pins enable reliable movement of the top ring when the top ring is being raised and lowered, as well as, when the top ring is being moved into and out of the process module during replacement. The collar defined in the lift pins allows the top member of the lift pin to pass through the mid ring to raise/lower the top ring (e.g., the edge ring). The presence of the collar also allows the mid ring to be raised and lowered, thereby allowing the mid ring to be replaced. The chamfer defined in the collar section allows a sleeve to engage with the collar so that the sleeve can engage with and move the mid ring.

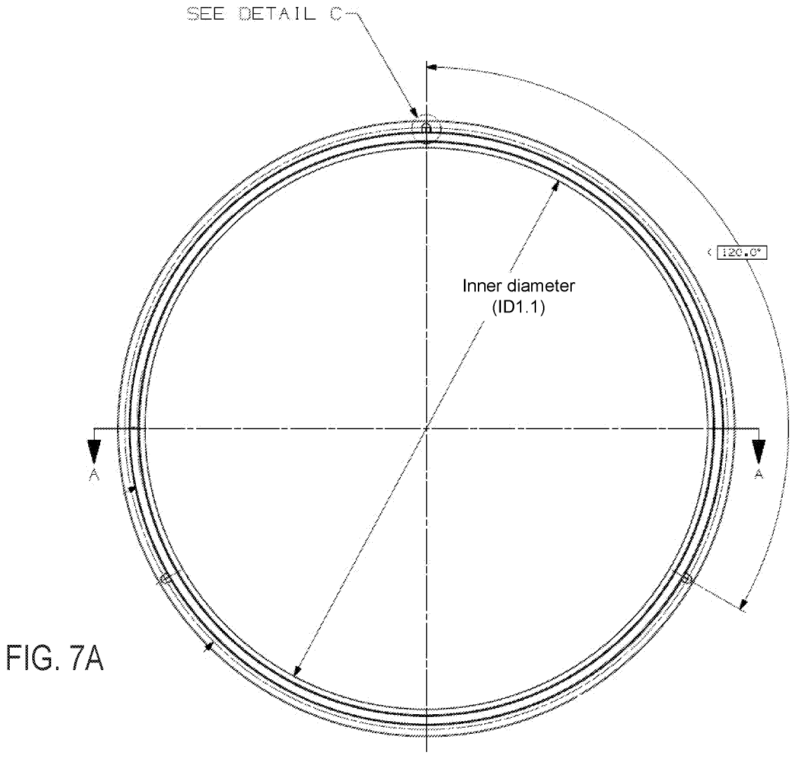

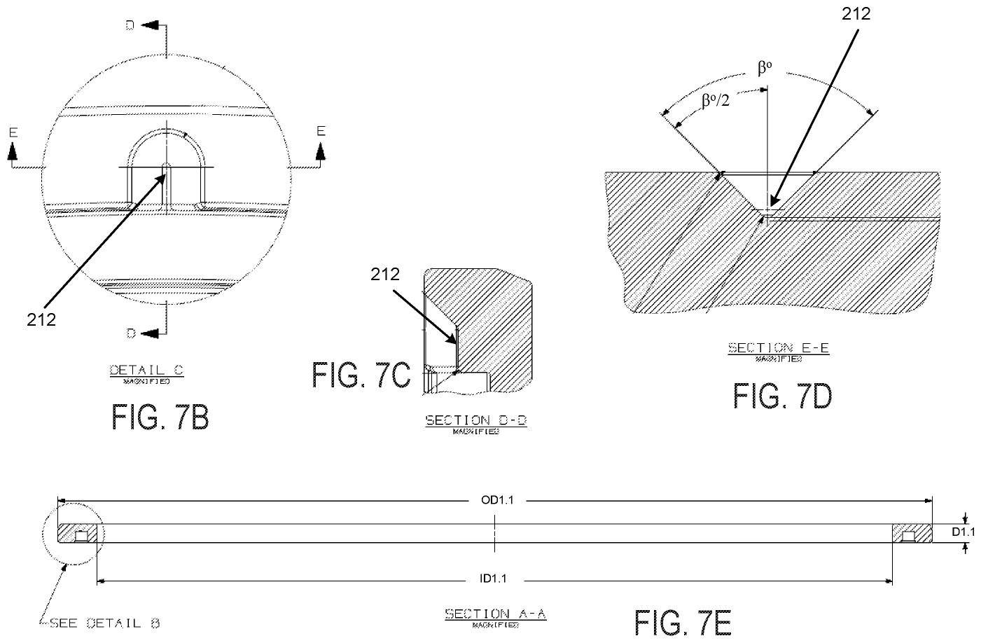

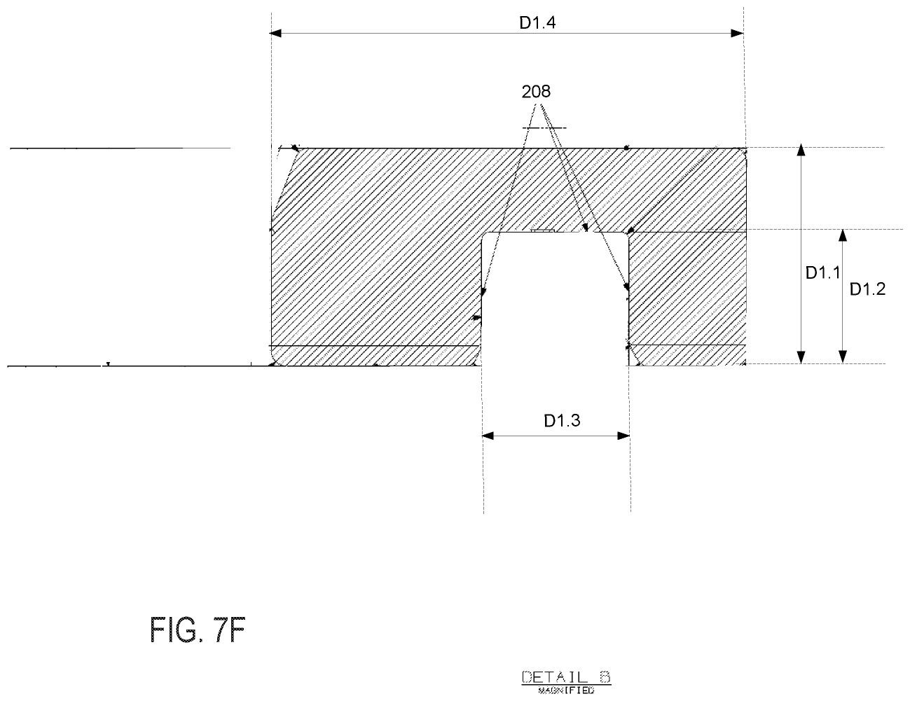

FIGS. 7A-7F illustrate a geometry of a first embodiment of the top ring that is used in the process module, in one implementation. The top ring is a tunable and replaceable edge ring, in one implementation. The first embodiment of the top ring illustrated in FIG. 7A includes a set of three grooves defined along a radial plane and located equidistant from one another. For instance, the grooves are disposed at 120° from one another. FIG. 7B illustrates a magnified view of section C of the first embodiment of the top ring identified in FIG. 7A. The magnified view of section C is a cross-sectional view of a groove defined in the top ring. The groove is defined adjacent to a channel and opens into the channel. The groove includes a pin contact position 212 where the top member of the lift pin contacts the top ring. The groove in this embodiment is shown to have sidewalls that meet at a tip which is rounded to form a u-shaped groove. A vertical cross-sectional view D-D of the groove identified in FIG. 7B, is shown in FIG. 7C. FIG. 7D illustrates a horizontal cross-sectional view E-E of the groove identified in FIG. 7B. In the implementation illustrated in FIG. 7D, the sidewalls of the groove are shown to be disposed at an angle β from one another. In some implementations, the angle β is set to be 90°. In an alternate implementation, the inclined sidewalls of the groove are defined to be less than 90°. In this implementation, a tip of the groove where the inclined sidewalls meet and where the lift pin contacts the groove (i.e., pin contact position 212), is rounded. FIG. 7E illustrates horizontal cross-sectional view A-A of the first embodiment of the top ring identified in FIG. 7A. The outer diameter of the top ring is “OD1.1” and an inner diameter of the top ring is “ID1.1”. In one implementation, the height of the top ring is “D1.1”.

FIG. 7F illustrates an expanded cross-sectional view of the channel defined on the bottom surface of the top ring identified as detail B in FIG. 7E. In one implementation, a height of the first embodiment of the top ring is “D1.1” and a height of the groove is “D1.2”. The width of the groove is “D1.3 and the width of the top ring is “D1.4”. The groove is defined with sidewalls 208. Although the illustrate in FIG. 7F shows vertical sidewalls 208 for the groove, the sidewalls 208 of the groove are inclined to allow the lift pin to slide to the bottom of the groove and rest at the pin contact position 212 (not shown). In one implementation, the height of the groove is shown to be between about 2 mm to about 2.3 mm. In one implementation the thickness or height of the top ring is between about 4 mm and about 5 mm. In one implementation, the inner diameter of the top ring may be between about 298 mm to about 303 mm. The outer diameter of the top ring may be between about 325 mm to about 330 mm. An outer edge of the top ring may be inclined at an angle. The geometry of the different components of the top ring is given just as an example and should not be considered limiting. Other ranges and measurements of the various components of the top ring and the dimensions of the top ring can also be envisioned. The geometry of the different components of the first embodiment of the top ring is given just as an example and should not be considered limiting. Other ranges and measurements of the various components of the top ring and the dimensions of the top ring can also be envisioned.

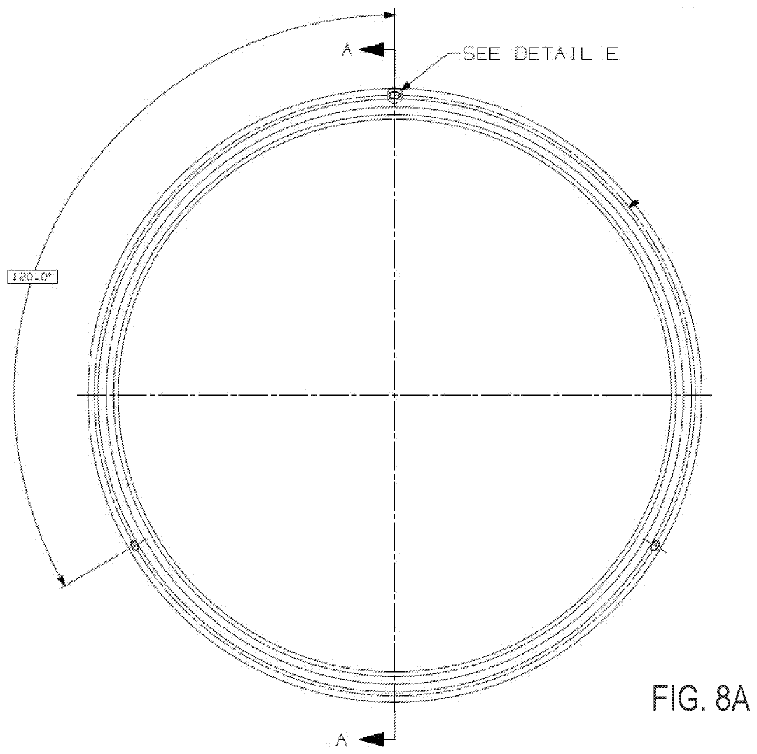

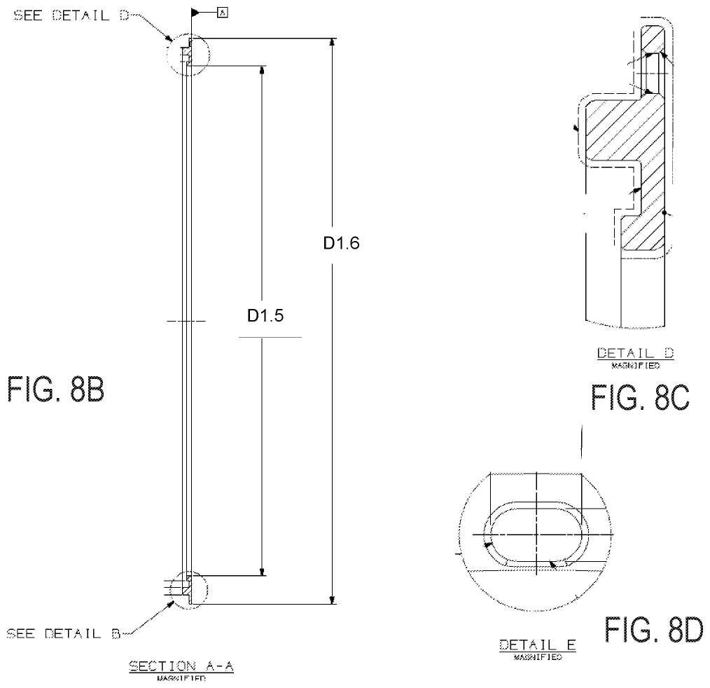

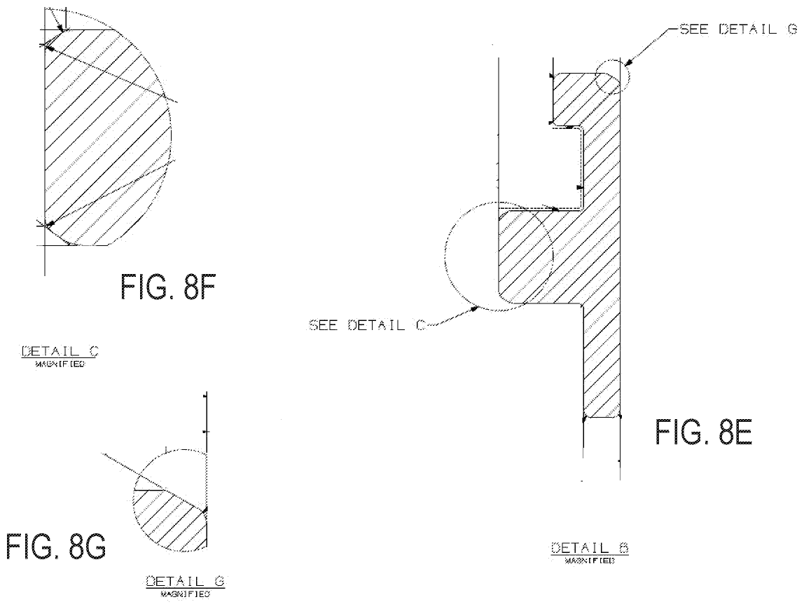

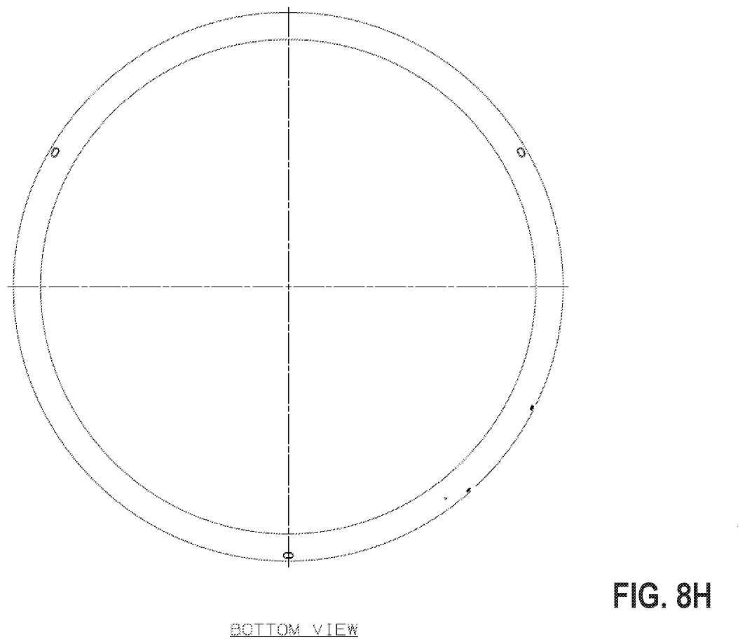

FIGS. 8A-8I illustrate a geometry of a first embodiment of a mid ring used in the process module that can be replaced. The first embodiment of the mid ring has an inner diameter that is equal to or less than an outer diameter of the surface receiving section of the inner electrode. In one implementation, an inner diameter of the mid ring is shown to be between about 295 mm to about 298 mm. As the substrate is shown to extend outside of the ESC surface and a standard substrate size is about 300 mm, the inner diameter of the mid ring is less than the outer diameter of the substrate so that it can cover an area below the edge of the substrate that extends outside of the ESC surface.

FIG. 8B illustrates cross-section view A-A identified in FIG. 8A showing surface dimensions of the first embodiment of the mid ring, in one implementation. As shown in FIG. 8B, the inner diameter of the mid ring is “D1.5” and an outer diameter is “D1.6”. In one implementation, the inner diameter of the first embodiment of the mid ring is between about 294 mm to about 298 mm and the outer diameter of the mid ring is between about 348 mm to about 353 mm. The aforementioned dimensions are provided as examples and should not be considered restrictive. Of course, the dimensions vary based on the size of the substrate, the size of the ESC and the size of the channels, grooves.

FIG. 8C illustrates an expanded view of an edge of the first embodiment of the mid ring, identified as section D in FIG. 8B, showing the different contours defined on the top surface of the first embodiment of the mid ring. FIG. 8D illustrates a magnified view of a portion of the mid ring identified as detail E in FIG. 8A. FIG. 8E illustrates a magnified view of an edge of the first embodiment of the mid ring identified as section B in FIG. 8B. FIG. 8F illustrates a magnified view of section C of the first embodiment of the mid ring illustrated in FIG. 8E. FIG. 8G illustrates a magnified view of section G of the mid ring illustrated in FIG. 8E. It should be noted that the geometry of the first embodiment of the top and the mid rings and the dimensions of the various components of the top and the mid rings are provided as examples and should not be considered restrictive or exhaustive. FIG. 8H illustrates a top view of a bottom surface of the first embodiment of the mid ring.

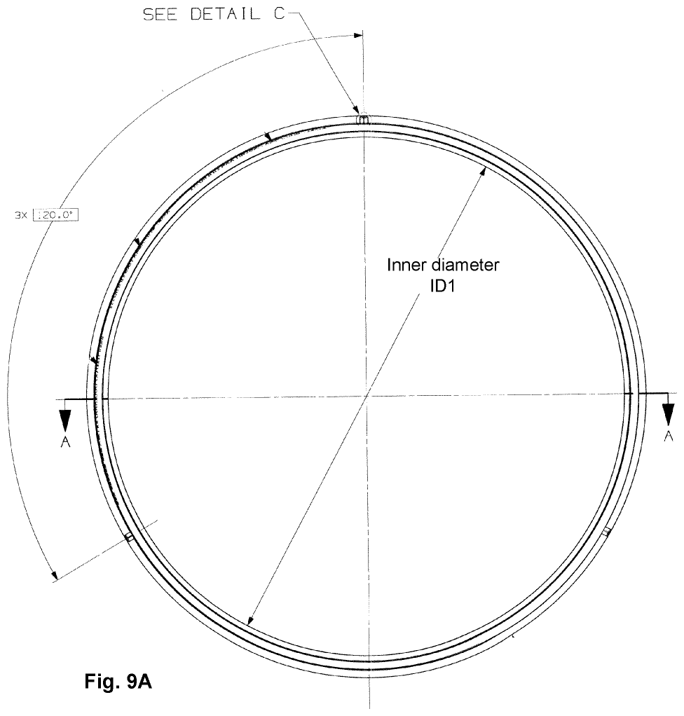

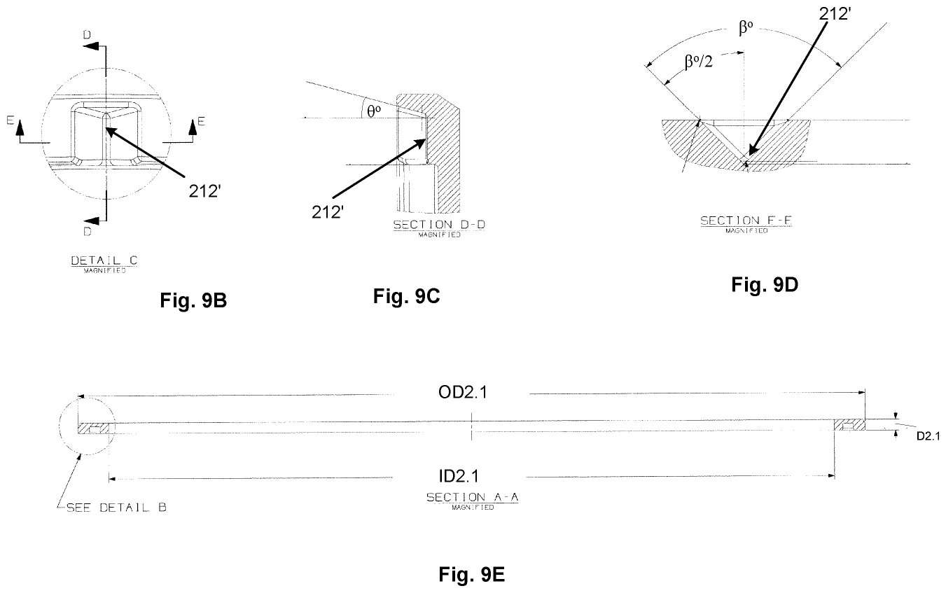

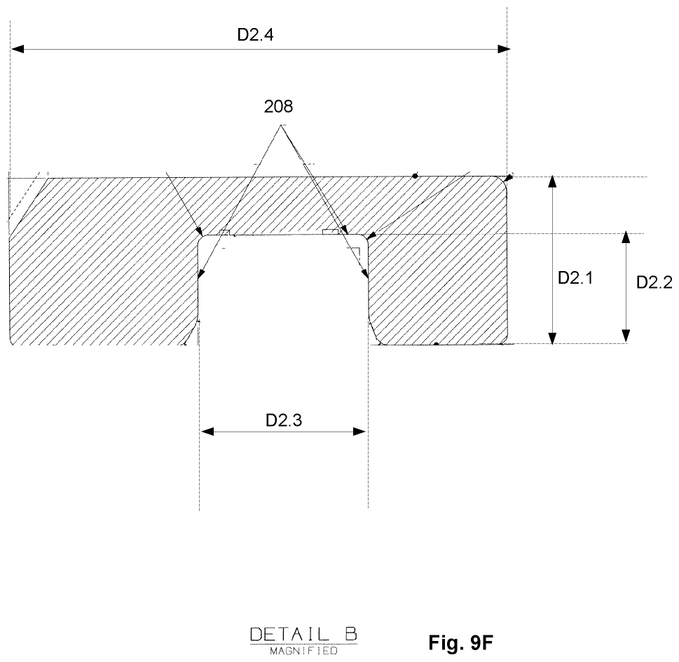

FIGS. 9A-9F illustrate a geometry of a second embodiment of a top ring that is used in the process module. The top ring is a tunable and replaceable edge ring, in one implementation. The second embodiment of the top ring illustrated in FIG. 9A includes a set of three grooves defined along a radial plane equidistant from one another. For instance, the grooves are disposed at 120° from one another. FIG. 9B illustrates a magnified view of section C of the second embodiment of the top ring identified in FIG. 9A. The magnified view of section C is a cross-sectional view of the groove defined on an underside surface of the top ring. The groove is defined adjacent to a channel and opens into the channel. The groove includes a pin contact position 212′ where the top member of the lift pin contacts the top ring. In the second embodiment of the top ring, the groove defined on the underside surface is a v-shaped groove. A vertical cross-sectional view D-D of the groove shown in FIG. 9B is illustrated in FIG. 9C. In one implementation, the sidewall of the groove is shown to be inclined at an angle θ. The angle θ at which the sidewall inclines is between about 20° and about 30°, in one implementation. In alternate implementation, the angle θ of the sidewall can be any angle that is less than 90°. FIG. 9D illustrates a horizontal cross-sectional view E-E of the groove shown in FIG. 9B. The angle of the v-groove is shown to be β. In some implementations, the angle β is set to be 90°. In an alternate implementation, the angle of the groove is defined to be less than 90°. In this implementation, a tip of the groove where the inclined sidewalls meet is sharp. FIG. 9E illustrates horizontal cross-sectional view A-A shown in FIG. 9A of the second embodiment of the top ring. This cross-sectional view does not show the grooves defined in the top ring. The outer diameter of the top ring is “OD2.1” and an inner diameter of the top ring is “ID2.1”. In one implementation, the height of the top ring is “D2.1”.

FIG. 9F illustrates an expanded cross-sectional view of the channel defined on the bottom surface of the second embodiment of the top ring. In one implementation, a height of the top ring is “D2.1” and a height of the groove is “D2.2”. The width of the groove is “D2.3 and the width of the top ring is “D2.4”. The groove is defined with sidewalls 208. Although the illustrate in FIG. 9F shows vertical sidewalls for the groove, the sidewalls of the groove are inclined to allow a lift pin that comes in contact with the sidewall of the groove to slide to the bottom of the groove and contact the pin contact position 212′ (not shown). In one implementation, the height of the groove is between about 2 mm to about 2.3 mm. In one implementation the thickness of the top ring is between about 4 mm and about 5 mm. In one implementation, the inner diameter (ID2.1) of the second embodiment of the top ring is between about 298 mm to about 303 mm. The outer diameter (OD2.1) of the second embodiment of the top ring may be between about 325 mm to about 330 mm. The geometry of the different components of the second embodiment of the top ring is given just as an example and should not be considered limiting. Other ranges and measurements of the various components of the second embodiment of the top ring and the dimensions of the second embodiment of the top ring can also be envisioned.

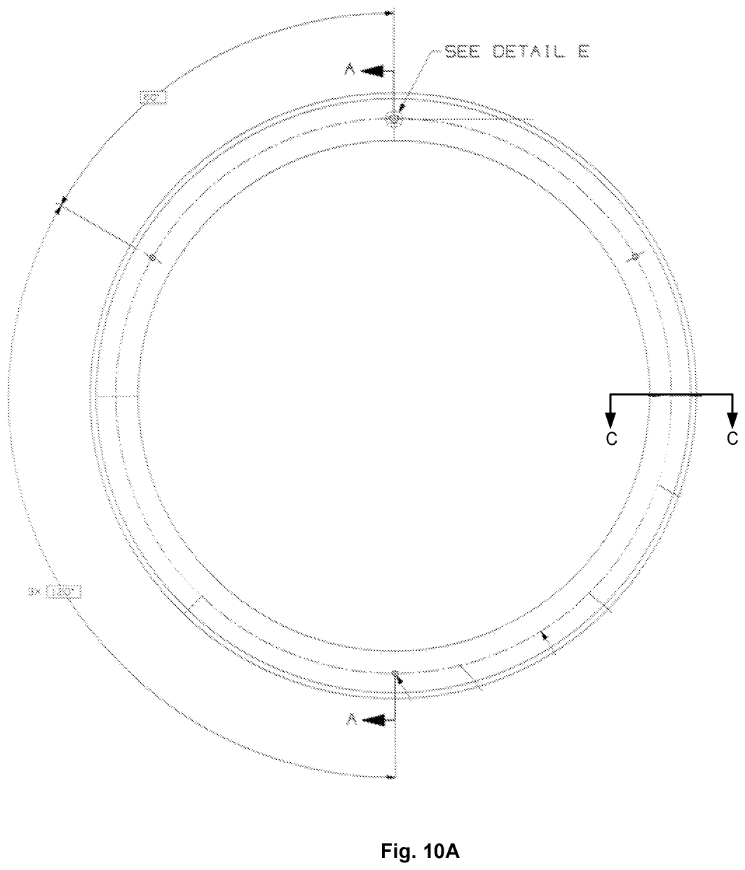

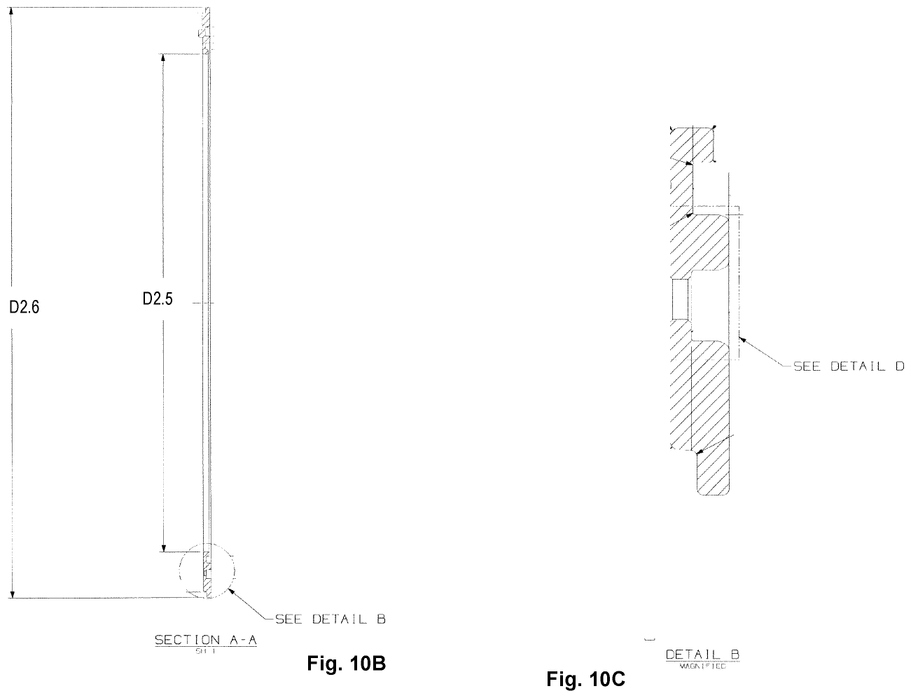

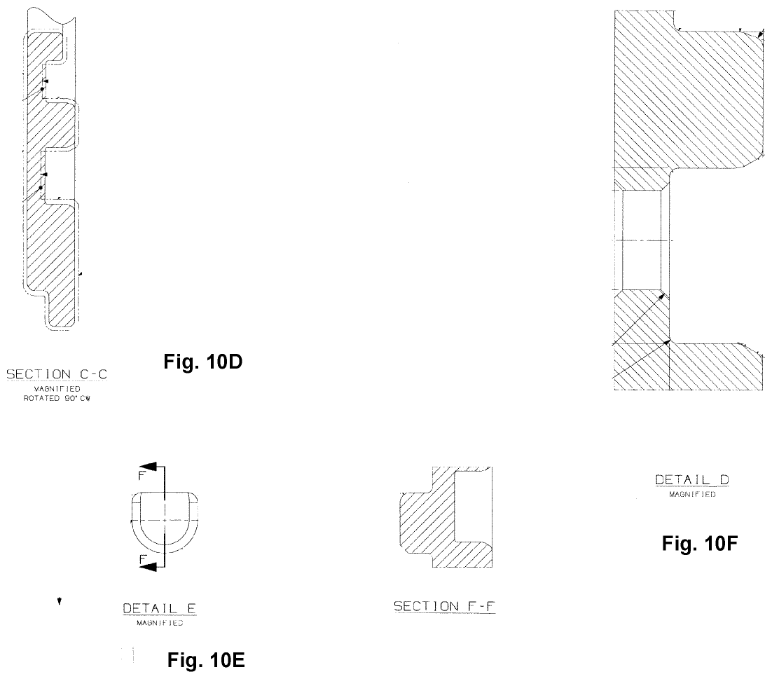

FIGS. 10A-10F illustrate a geometry of a second embodiment of a mid ring used in the process module, which can be replaced, in one implementation. FIG. 10A shows a top view of a top surface of the second embodiment of the mid ring. FIG. 10B illustrates a sectional view A-A of the second embodiment of the mid ring illustrated in FIG. 10A. The second embodiment of the mid ring has an inner diameter D2.5 and an outer diameter D2.6 that is equal to or less than an outer diameter of the surface receiving surface of the inner electrode. In one implementation, the inner diameter of the second embodiment of the mid ring is shown to be between about 294 mm to about 298 mm and the outer diameter of the mid ring is between about 348 mm to about 353 mm. As the substrate is shown to extend outside of the ESC surface and a standard substrate size is about 300 mm, the inner diameter of the second embodiment of the mid ring is less than the outer diameter of the substrate so that it can cover an area below the edge of the substrate that extends outside of the ESC surface. The aforementioned dimensions are provided as examples and should not be considered restrictive. Of course, the dimensions vary based on the size of the substrate, the size of the ESC and the size of the channels, grooves.

FIG. 10C illustrates an expanded view of detail B of an edge of the second embodiment of the mid ring illustrated in FIG. 10B. FIG. 10D illustrates a magnified view of section C-C of the second embodiment of the mid ring identified in FIG. 10A. FIG. 10E illustrates a magnified view of detail E identified in FIG. 10A and a cross-section F-F identified within detail E. FIG. 10F illustrates a magnified view of detail D identified in FIG. 10C. It should be noted that the geometry of the second embodiment of the top and the mid rings and the dimensions of the various components of the second embodiment of the top and the mid rings are provided as examples and should not be considered restrictive or exhaustive.

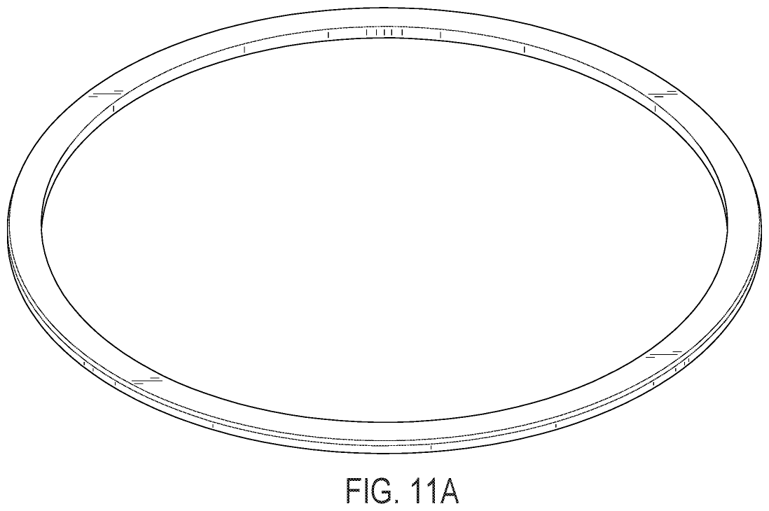

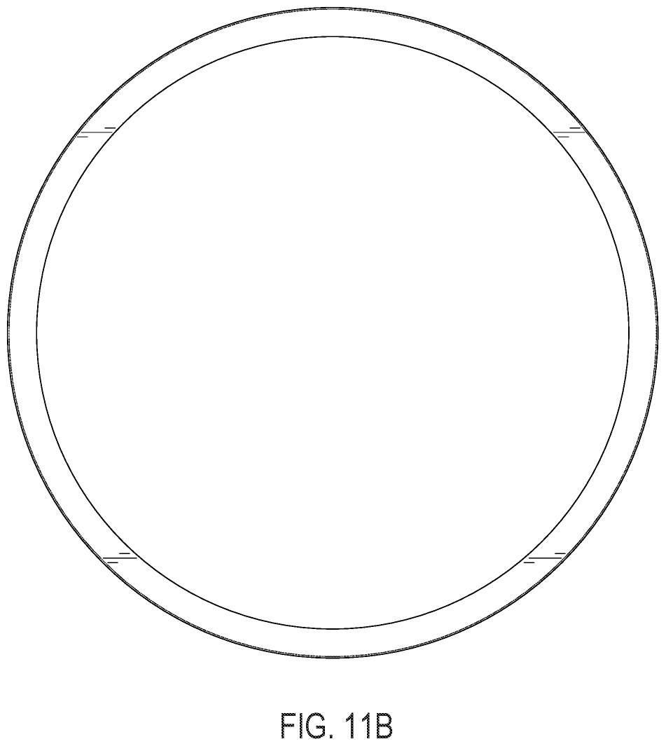

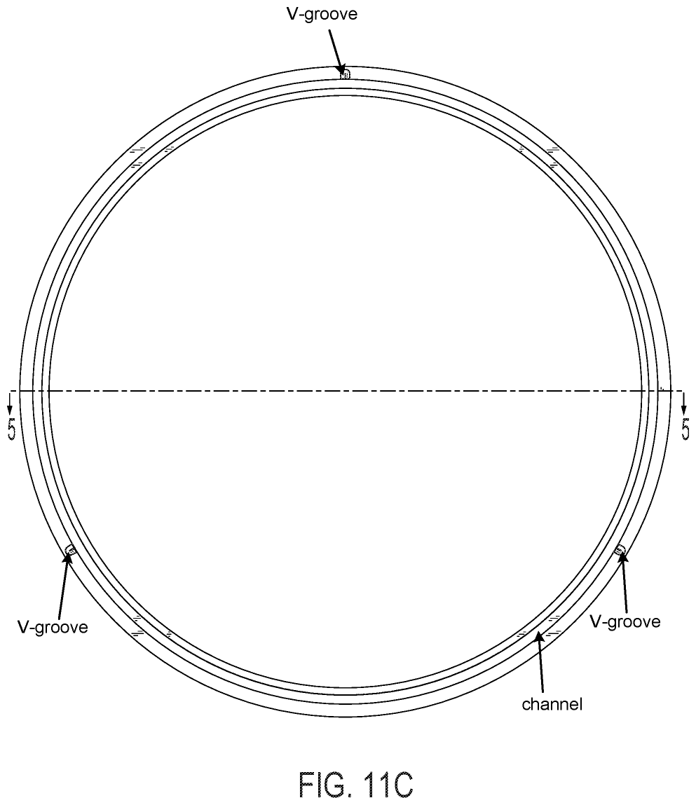

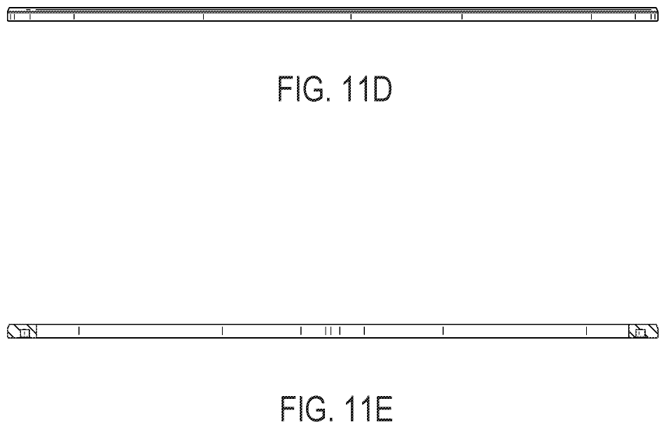

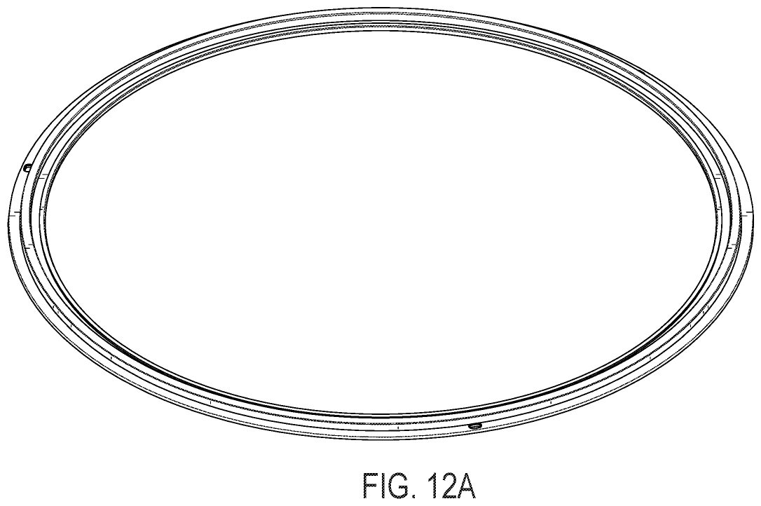

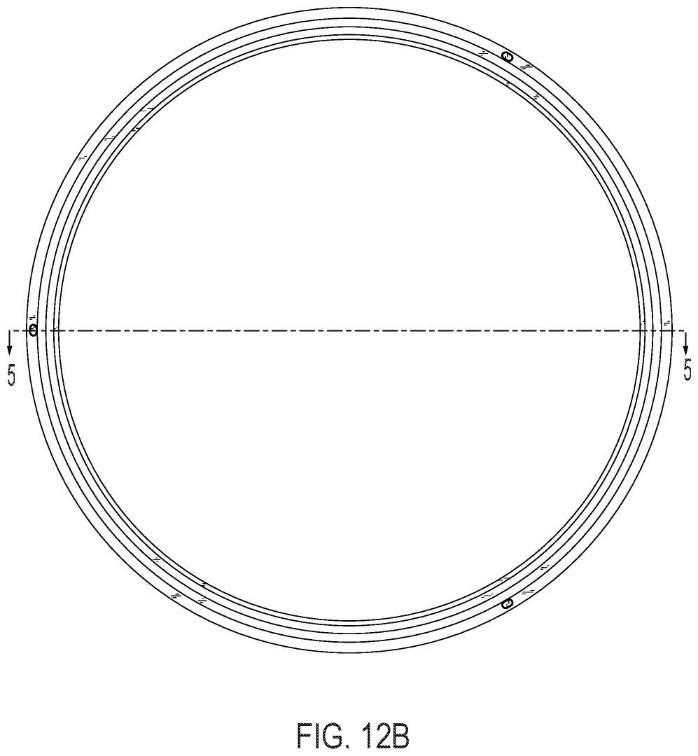

FIG. 11A illustrates a perspective view of a first embodiment of a top ring used in the process module. FIG. 11B illustrates a top view of a top surface of the first embodiment of a top ring. FIG. 11C illustrates a top view of a bottom surface of the first embodiment of the top ring. FIG. 11D illustrates a side view of the first embodiment of the top ring. FIG. 11E illustrates a side cross-sectional view of the first embodiment of the top ring.

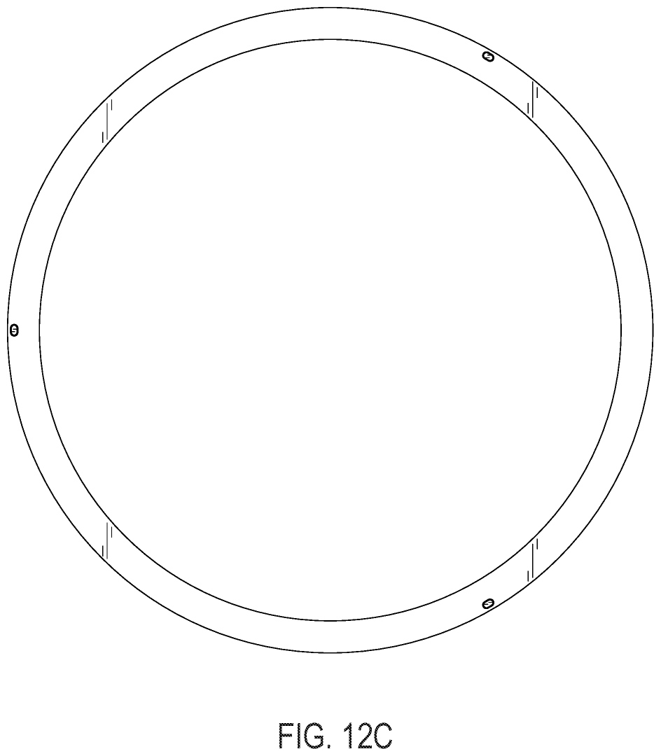

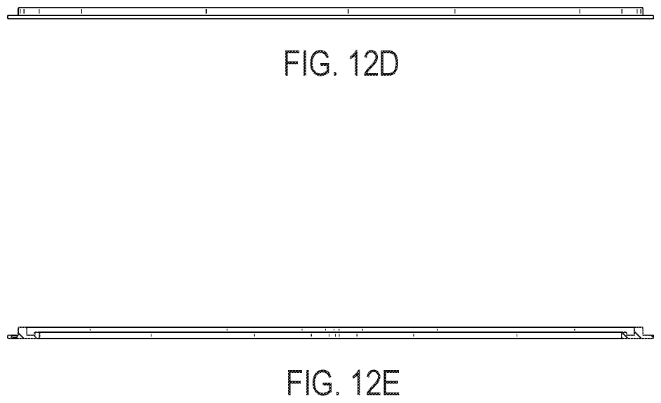

FIG. 12A illustrates a perspective view of a first embodiment of a mid ring used in the process module. FIG. 12B illustrates a top view of a top surface of the first embodiment of the mid ring. FIG. 12C illustrates a top view of a bottom surface of the first embodiment of the mid ring. FIG. 12D illustrates a side view of the first embodiment of the mid ring. FIG. 12E illustrates a side cross-sectional view of the first embodiment of the mid ring.

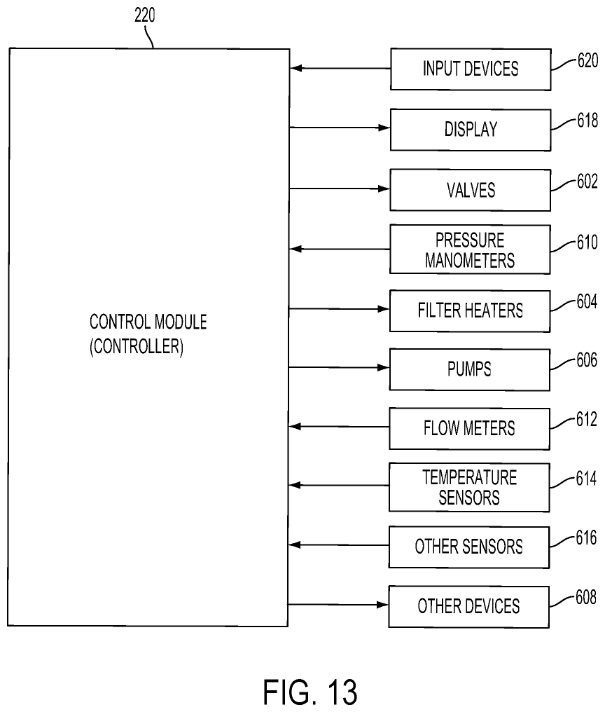

FIG. 13 shows a sample control module (also referred to as a “controller”) 220 for controlling the substrate processing system described above. In one embodiment, the controller 122 may include some example components, such as a processor, memory and one or more interfaces. The controller 122 may be a separate computing device that is communicatively connected to computer 124 or may be part of the computer 124. The controller 122 may be employed to control devices in a substrate processing system 100 based in part on sensed values. For example only, the controller 122 may control one or more of valves 602 (including isolation valves/gates), filter heaters 604, pumps 606, and other devices 608 based on the sensed values and other control parameters. The controller 122 receives the sensed values from, for example only, pressure manometers 610, flow meters 612, temperature sensors 614, and/or other sensors 616. The controller 122 may also be employed to control process conditions during precursor delivery and deposition of a film. The controller 122 will typically include one or more memory devices and one or more processors.

The controller 122 may control activities of the precursor delivery system and deposition apparatus. The controller 122 executes computer programs including sets of instructions for controlling process timing, delivery system temperature, pressure differentials across the filters, valve positions, robots and end effectors, mixture of gases, chamber pressure, chamber temperature, wafer temperature, RF power levels, wafer chuck or pedestal position, and other parameters of a particular process. The controller 122 may also monitor the pressure differential and automatically switch vapor precursor delivery from one or more paths to one or more other paths. Other computer programs stored on memory devices associated with the controller 122 may be employed in some embodiments.

Typically there will be a user interface associated with the controller 122. The user interface may include a display 618 (e.g. a display screen and/or graphical software displays of the apparatus and/or process conditions), and user input devices 620 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module (i.e., controller) parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber or process module components necessary to carry out the inventive deposition processes. Examples of programs or sections of programs for this purpose include substrate positioning code, process gas control code, pressure control code, heater control code, plasma control code, lift pin mechanism control code, robot position code, end effector position code and valve position control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck. The valve position control code may include code to control access to a process module or the substrate processing system by controlling isolation valves that provide access to the process module or the cluster tool, for example. The lift pin mechanism control code may include code to activate the actuator drive to cause the actuators to move the lift pins, for example. The robot position code may include code to manipulate the position of the robot(s) including manipulation of the robot to move along a lateral, a vertical, or a radial axis, for example. The end effector position code may include code to manipulate the position of the end effector including manipulation of the robot to extend, contract, or move along a lateral, a vertical or radial axis, for example.

Examples of sensors that may be monitored during deposition include, but are not limited to, mass flow control modules, pressure sensors such as the pressure manometers 610, and thermocouples located in delivery system, the pedestal or chuck (e.g. the temperature sensors 614). Appropriately programmed feedback and control algorithms may be used with data from these sensors to maintain desired process conditions. The foregoing describes implementation of embodiments of the invention in a single or multi-chamber semiconductor processing tool.

The various embodiments described herein allow the consumable parts to be replaced in a fast and efficient manner without having to open the substrate processing system to Atmospheric conditions. As a result, the time to replace consumable parts, as well as any risk of contaminating the chamber during replacement of consumable parts is greatly reduced, thereby allowing the substrate processing system to come online faster. Further, risk of inadvertent damage to the process module, the consumable part and to other hardware components in the process module are greatly reduced.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A lift pin mechanism employed within a process module of a substrate processing system to replace a top ring and a mid ring used in the process module, comprising:
a plurality of lift pins to support the top ring and the mid ring, when engaged, each lift pin of the plurality of lift pins includes a top member and a bottom member, the top member separated from the bottom member by a collar defined by a chamfer,
wherein the top member is configured to extend through a sleeve defined in a housing within a body of a lower electrode disposed in the process module in which the substrate is received for processing, and engage with an underside surface of the top ring, and
wherein the collar of the lift pin is configured to engage with a bottom surface of the sleeve, a top surface of the sleeve configured to engage with a bottom side of the mid ring, when the plurality of lift pins are activated;
an actuator coupled to each lift pin of the plurality of lift pins, the actuators of the plurality of lift pins connected to an actuator drive that provides power to drive the actuators; and
a controller connected to the actuator drive to control movement of the plurality of lift pins.

2. The lift pin mechanism of claim 1, wherein the plurality of lift pins are distributed uniformly along a circumference of the lower electrode defined in the process module.

3. The lift pin mechanism of claim 1, wherein the top member of the lift pin is configured to extend through a channel defined in the mid ring, a size of the channel is less than a size of the bottom member of the lift pin.

4. The lift pin mechanism of claim 3, wherein a diameter of the bottom member of the lift pin is greater than a diameter of the top member, and wherein a diameter of the channel in the mid ring is defined to be smaller than the diameter of the bottom member and greater than the diameter of the top member.

5. The lift pin mechanism of claim 1, wherein the top member is used to support and move the top ring to a ring transfer plane defined for the process module, the ring transfer plane representing a replacement position from where an arm of a robot of the substrate processing system accesses the top ring during removal of the top ring from the process module, and
wherein the bottom member is used to move the sleeve that is supporting the mid ring up to the ring transfer plane for the arm of the robot to remove the mid ring.

6. The lift pin mechanism of claim 1, wherein the top member and the bottom of the lift pin are configured to move the top ring and the mid ring separately.

7. The lift pin mechanism of claim 1, wherein the top member and the bottom member of the plurality of lift pins are configured to move the top ring and the mid ring simultaneously.

8. The lift pin mechanism of claim 1, wherein a length of the top member is defined to allow the lift pin to move the top ring to a replacement position in the process module.

9. The lift pin mechanism of claim 1, wherein a length of the bottom member is defined to allow the lift pin to move the mid ring to a replacement position in the process module.

10. The lift pin mechanism of claim 1, wherein the top ring is a tunable and replaceable edge ring used in the process module, and the mid ring is a replaceable component of the process module.

11. The lift pin mechanism of claim 1, wherein the plurality of lift pins includes a set of 3 lift pins distributed along the circumference of the lower electrode, such that a distance of the 3 lift pins from a center of the lower electrode is equal to at least a radius of the top ring.

12. The lift pin mechanism of claim 1, wherein the top ring includes a plurality of grooves defined on an underside surface, the plurality of grooves distributed uniformly along the bottom surface, wherein the top member of each of the lift pins aligns and engages with a corresponding groove, when the lift pin mechanism is activated.

13. The lift pin mechanism of claim 1, wherein the plurality of lift pins includes a first set of lift pins used for tuning the top ring, and a second set of lift pins for replacing the top ring and the mid ring, the first set of lift pins being offset from the second set of lift pins, an amount of offset based on a size of grooves defined on an underside surface of the top ring, such that each of the first set and the second set of lift pins contacts a portion of an inclined sidewall of a corresponding groove.

14. The lift pin mechanism of claim 13, wherein each of the first set of lift pins and the second set of lift pins include at least 3 lift pins distributed radially equidistant from one another and disposed at a distance equal to at least a radius of the top ring.

15. The lift pin mechanism of claim 1, wherein the lift pins are made of sapphire, wherein the mid ring is made of quartz or silicon carbide, and wherein the top ring is made of quartz.

16. The lift pin mechanism of claim 1, wherein the top member of the lift pin is about 40 mms in diameter and the bottom member is about 60 mms in diameter.

17. A process module within a substrate processing system used to process a substrate, comprising:
a top electrode having a plurality of outlets distributed uniformly along a horizontal plane, the plurality of outlets coupled to a process chemistry source and configured to provide process chemistry to the process module for generating plasma, the top electrode being electrically grounded;
a lower electrode disposed opposite to the top electrode and configured to support the substrate received for processing, the lower electrode connected to a power source to provide power to generate the plasma, the lower electrode including,
a bottom ring disposed in a body of the lower electrode proximal to an outer edge, a housing extending from a top surface of the bottom ring downward into a body of the bottom ring, the housing configured to house a sleeve;
a mid ring disposed immediately above and aligned with the bottom ring, the mid ring having a channel defined therethrough;
a top ring disposed immediately above and aligned with the mid ring such that a top surface of the top ring is co-planar with a top surface of the substrate received on the lower electrode; and
a lift pin mechanism including,
a plurality of lift pins, each lift pin of the plurality of lift pins including a top member and a bottom member, the top member separated from the bottom member by a collar defined by a chamfer, the plurality of lift pins distributed uniformly along a circumference of the lower electrode so as to align with the bottom ring, the mid ring and the top ring;
an actuator coupled to each lift pin of the plurality of lift pins, the actuators of the plurality of lift pins connected to an actuator drive that provides power to drive the actuators.

18. The process module of claim 17, wherein the actuator drive is connected to a controller to control movement of the plurality of lift pins, and wherein the controller is a computing device or coupled to a computing device, the computing device used to provide input to control movement of the plurality of lift pins.

19. The process module of claim 17, wherein a top surface of the mid ring is contoured to define a mating surface, and a bottom surface of the top ring is contoured to complement with the contour of the mating surface of the mid ring.

20. The process module of claim 17, wherein lift pins of the lift pin mechanism are defined in the body of the lower electrode so as to align with the channel defined in the mid ring and with the housing defined in the bottom ring, the aligning of the lift pins allows the top member to extend through the channel and the housing, and the bottom member to engage with the sleeve and extend with the sleeve through the bottom ring to a bottom surface of the mid ring.

21. The process module of claim 17, wherein the power source is a radio frequency (RF) power source and the lower electrode is connected to the RF power source through a matching network.

22. The process module of claim 17, wherein the channel in the mid ring is sized to allow the top member of the lift pin to extend through.

23. The process module of claim 17, wherein a diameter of the bottom member of the lift pin is greater than a diameter of the top member, and wherein a diameter of the channel in the mid ring is defined to be smaller than the diameter of the bottom member and greater than the diameter of the top member.

24. A ring unit disposed in a lower electrode of a process module within a substrate processing system used for processing a substrate, comprising:
a top ring disposed in the lower electrode, the top ring including,
a top surface that is planar, the top surface defined so as to be co-planar with a top surface of the substrate, when received on the lower electrode;
a bottom surface of the top ring includes a channel running along a center portion of the bottom surface, the channel of the top ring separating a bottom outer surface from a bottom inner surface, a plurality of grooves defined along the bottom outer surface and adjacent to the channel such that an opening of each of the plurality of grooves opens into the channel, the plurality of grooves engaged by lift pins of a lift pin mechanism when the top ring is to be moved; and
a mid ring disposed immediately below the top ring such that the mid ring aligns with the top ring, the mid ring includes a channel defined in a vertical orientation within a body so as to allow a portion of a lift pin to extend through, a bottom surface of the mid ring being planar and a top surface of the mid ring having a contour that matches with a contour defined on the bottom surface of the top ring, so as to provide a reliable mating surface, when the top ring and the mid ring are in an installed position.

25. The ring unit of claim 24, wherein the channel of the mid ring is sized to allow a top member of the lift pin to slide through and to prevent a bottom member of the lift pin from sliding through.
